(19) United States
(12) Patent Application Publication
(10) Pub. No.: US 2015/0079757 A1
(43) Pub. Date: Mar. 19, 2015

(54) METHOD OF FABRICATING SEMICONDUCTOR DEVICE

(71) Applicants: Kyung-Yub JEON, Yongin-si (KR); Jun-ho YOON, Suwon-si (KR); Min-joon PARK, Yongin-si (KR)

(72) Inventors: Kyung-Yub JEON, Yongin-si (KR); Jun-ho YOON, Suwon-si (KR); Min-joon PARK, Yongin-si (KR)

(21) Appl. No.: 14/299,287

(22) Filed: Jun. 9, 2014

(30) Foreign Application Priority Data
Sep. 16, 2013 (KR) 10-2013-0111148

(51) Int. Cl. H01L 21/033; H01L 49/02; H01L 21/768; H01L 21/311

(52) U.S. Cl. CPC H01L 21/0337; H01L 21/31144; H01L 28/40; H01L 21/76811; H01L 21/76825; H01L 21/76826; H01L 21/76828; H01L 21/76877; H01L 21/0332; H01L 21/0335; H01L 21/0338
USPC 438/396; 438/702; 438/637

(57) ABSTRACT

A method of fabricating a semiconductor device is provided and includes forming one or more molding layers on a substrate, forming a silicon mask layer, first and second mask layers, and a mask pattern having a different etch selectivity to be vertically aligned on the molding layer, patterning the second mask layer with a second mask pattern using the mask pattern as an etching mask, patterning the first mask layer with a first mask pattern using the second mask pattern as an etching mask, patterning the silicon mask layer with a silicon mask pattern using the first mask pattern as an etching mask, changing the silicon mask pattern to a hard mask pattern having an improved etch selectivity by doping impurities into the silicon mask pattern, forming a hole having a high aspect ratio contact (HARC) structure vertically passing through the molding layer using the hard mask pattern as an etching mask, and removing the hard mask pattern.

### CROSS-REFERENCE TO RELATED APPLICATIONS

This application claims priority under 35 U.S.C. §119 (a) to Korean Patent Application No. 10-2013-0111148 filed on Sep. 16, 2013 in the Korean Intellectual Property Office, the disclosure of which is hereby incorporated by reference in its entirety.

### BACKGROUND

1. Field

The present general inventive concept relates to a method of fabricating a semiconductor device using a hard mask.

2. Description of the Related Art

As semiconductor devices become highly integrated and patterns become highly miniaturized, a contact having a high aspect ratio (HAR) is needed. A hard mask having the HAR is required in order to form the contact.

### SUMMARY

The present general inventive concept provides a method of fabricating a semiconductor device using a hard mask having an improved etch selectivity.

Additional features and utilities of the present general inventive concept will be set forth in part in the description which follows and, in part, will be obvious from the description, or may be learned by practice of the general inventive concept.

The foregoing and/or other features and utilities of the present general inventive concept are achieved by providing a method of fabricating a semiconductor device that includes forming one or more molding layers on a substrate, forming a silicon mask layer, first and second mask layers, and a mask pattern having a different etch selectivity to be vertically aligned on the molding layer, patterning the second mask layer with a second mask pattern using the mask pattern as an etching mask, patterning the first mask layer with a first mask pattern using the second mask pattern as an etching mask, patterning the silicon mask layer with a silicon mask pattern using the first mask pattern as an etching mask, changing the silicon mask pattern to a hard mask pattern in which etch selectivity is improved by doping impurities into the silicon mask pattern, forming a hole having a high aspect ratio contact (HARC) structure vertically passing through the molding layers using the hard mask pattern as an etching mask, and removing the hard mask pattern.

Here, the impurities may include one of boron (B), argon (Ar), carbon (C) and phosphorus (P).

Here, the first mask layer may include one of an amorphous carbon layer (ACL) and a spin-on hard mask (SOH).

Here, the second mask layer may include one of silicon oxide, silicon nitride, and silicon oxynitride.

Here, the mask pattern may include a photoresist.

Changing the silicon mask pattern to a hard mask pattern may include directly doping the impurities into the silicon mask pattern by performing an ion implantation process.

Changing the silicon mask pattern to a hard mask pattern may include doping the impurities into the silicon mask pattern in a gas phase by performing an annealing process in a chamber in which gases including the impurities are injected. Herein, the annealing process may be performed at a temperature within a range of 500° C. to 800° C.

Changing the silicon mask pattern to a hard mask pattern may include conformally forming a heterogeneous film on the silicon mask pattern by performing a deposition process, and doping the impurities into the silicon mask pattern with inter-diffusion of the impurities between the silicon mask pattern and the heterogeneous film by performing an annealing process. Herein, the heterogeneous film may include one of boron silicate glass (BSG), phosphorus silicate glass (PSG) and arsenic silicate glass (ASG), and the annealing process may include spike annealing at a temperature within a range of about 950° C. to 1050° C. In addition, the method may further include conformally forming a heterogeneous film capping layer on the heterogeneous film after forming the heterogeneous film.

Removing the hard mask pattern may include performing a wet etching process using an etchant including ammonia water.

Removing the hard mask pattern may include forming a sacrificial layer in the hole, exposing the molding layer by performing a planarization process, and removing the sacrificial layer.

The foregoing and/or other features and utilities of the present general inventive concept may also achieved by providing a method of fabricating a semiconductor device that includes forming a unit device on or in a substrate, forming a molding layer covering the unit device on or in the substrate, forming a silicon mask layer on the molding layer, patterning the silicon mask layer with a silicon mask pattern, changing the silicon mask pattern to hard mask pattern by doping impurities into the silicon mask pattern, forming a hole having an HARC structure vertically passing through the molding layer using the hard mask pattern as an etching mask and exposing the substrate or the unit device, removing the hard mask pattern, and forming a capacitor structure or a contact plug electrically connected to the substrate or the unit device in the hole.

The foregoing and/or other features and utilities of the present general inventive concept are achieved by providing a method of fabricating a semiconductor device, comprising forming a silicon mask layer on a top surface of a molding layer, the silicon layer being partially covered by at least one mask pattern, patterning the silicon mask layer using the at least one mask pattern to form a silicon mask pattern, changing the silicon mask pattern to a hard mask pattern having an increased etch selectivity, and forming a hole vertically passing through the hard mask pattern and the molding layer using the hard mask pattern as an etch mask to expose an electrical component covered by the molding layer.

The at least one mask pattern may include a first mask pattern from a first mask pattern and a second mask pattern from a second mask layer, such that the first and the second mask patterns are vertically aligned with each other, and the first mask pattern is used as an etch mask for the silicon mask layer to form the silicon mask pattern.

The first mask layer, the second mask layer, and the silicon mask layer may have different etch selectivity.

The first mask layer may include one of an amorphous carbon layer (ACL) and a spin-on hard mask (SOH).

The second mask layer may include one of silicon oxide, silicon nitride, and silicon oxynitride.

The silicon mask pattern may be doped with impurities to form the hard mask pattern.

The impurities include one of boron (B), argon (Ar), carbon (C) and phosphorus (P).

Doping the impurities may include at least one of directly doping the impurities by an ion implantation process, injecting gases including the impurities by an annealing process, and inter-diffusing the impurities by an annealing process between the silicon mask pattern and a heterogeneous film disposed on top of the silicon mask pattern.

The hole may have a high aspect ratio contact (HARC) structure.

The method may further include removing the silicon mask pattern.

### BRIEF DESCRIPTION OF THE DRAWINGS

The above and/or other features and utilities of the present general inventive concept will become apparent and more readily appreciated from the following description of the embodiments, taken in conjunction with the accompanying drawings of which:

FIGS. 1 through 18 are longitudinal sectional views to describe a method used to fabricate a semiconductor device in accordance with an exemplary embodiment of the present general inventive concept.

FIGS. 19 through 37 are longitudinal sectional views to describe a method of fabricating a semiconductor device in accordance with an exemplary embodiment of the present general inventive concept;

FIGS. 38 through 52 are longitudinal sectional views to describe a method used to fabricate a semiconductor device in accordance with an exemplary embodiment of the present general inventive concept.

FIG. 53A is a schematic view illustrating a semiconductor module including semiconductor devices in accordance with an exemplary embodiment of the present general inventive concept;

FIG. 53B is a schematic block diagram illustrating an electronic system including semiconductor devices in accordance with an exemplary embodiment of the present general inventive concept;

FIG. 53C is a schematic block diagram illustrating another electronic system including semiconductor devices in accordance with an exemplary embodiment of the present general inventive concept; and

FIG. 53D is a schematic view illustrating a mobile apparatus including at least one of semiconductor devices in accordance with an exemplary embodiment of the present general inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

The terminology used herein to describe exemplary embodiments of the present general inventive concept is not intended to limit the scope of the present general inventive concept. The articles “a,” “an,” and “the” are singular in that they have a single referent, however the use of the singular form in the present document should not preclude the presence of more than one referent. In other words, elements of the present inventive concept referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Exemplary embodiments of the present general inventive concepts are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present general inventive concept.

Unless otherwise defined, all terms (including technical and scientific terms) used herein have the same meaning as commonly understood by one of ordinary skill in the art to which the present general inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

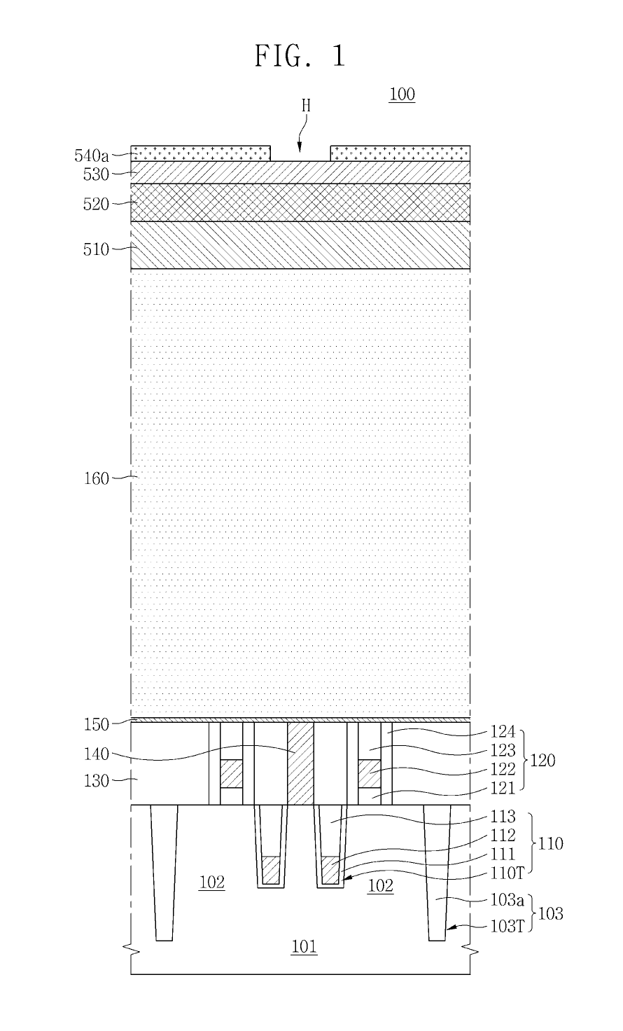

FIGS. 1 through 18 are vertical cross-sectional views describing a method of fabricating a semiconductor device 100 in accordance with exemplary embodiments of the present general inventive concept. The semiconductor device 100 may include a semiconductor device having a capacitor of one cylinder storage (OSC) structure.

Referring to FIG. 1, the method of fabricating the semiconductor device 100 may include forming field regions 103 defining an active region 102 in a substrate 101, forming gate structures 110 in a buried fashion in the substrate 101, forming bit line structures 120 on the active region 102 in the substrate 101, and forming a landing pad 140 on the active region 102 in the substrate 101. In addition, the method may include forming a stopping insulating layer 150 on the bit line structures 120 and the landing pad 140, forming a molding layer 160 on the stopping insulating layer 150, forming a silicon mask layer 510 on the molding layer 160, forming a first mask layer 520 on the silicon mask layer 510, forming a second mask layer 530 on the first mask layer 520, and forming a mask pattern 540a on the second mask layer 530.

Here, the substrate 101 may include a single crystalline silicon wafer, a silicon on insulator (SOI) wafer, a silicon-germanium wafer, but is not limited thereto.

In some exemplary embodiments of the present general inventive concept, forming the field regions 103 in the substrate 101 may include forming field trenches 103T in the substrate 101, and filling the field trenches 103T with field insulators 103a. The active region 102 may be defined by forming the field regions 103. The field insulators 103a may include silicon oxide.

Forming the gate structures 110 may include forming gate trenches 110T in the active region 102 in the substrate 101, conformally forming gate insulating layers 111 on inner walls of the gate trenches 110T, forming gate electrodes 112 on the gate insulating layers 111 in the gate trenches 110T, and forming gate capping layers 113 on the gate electrodes 112 in order to fill the gate trenches 110T. The gate insulating layers 111 may include a metal oxide, such as oxidized silicon, hafnium oxide, or an aluminum oxide, but are not limited thereto. The gate electrodes 112 may include a metal or a metal compound, such as titanium nitride (TiN), tungsten (W), other metal and/or metal compound multi-layers, but are not limited thereto. The gate capping layers 113 may include silicon nitride or silicon oxide.

Forming the bit line structures 120 may include forming bit line contact plugs 121 electrically connected to the active region 102 in the substrate 101, forming bit line electrodes 122 on the bit line contact plugs 121, forming bit line capping layers 123 on the bit line electrodes 122, and forming bit line spacers 124 on sides of the bit line electrodes 122 and the bit line capping layers 123. The bit line spacers 124 may cover sides of the bit line contact plugs 121. Forming the bit line contact plugs 121 may include forming conductors in direct contact with the active region 102. In addition, forming the bit line contact plugs 121 may include forming a silicide layer or a metal layer on the active region 102. Forming the bit line electrodes 122 may include forming a conductor, such as a metal, on the bit line contact plugs 121. Forming the bit line electrodes 122 may include forming a metal, such as tungsten (W), but are not limited thereto. Forming the bit line capping layers 123 may include forming silicon nitride by performing a deposition process. Forming the bit line spacers 124 may include forming silicon nitride by performing a deposition process, and performing an etch-back process.

Forming interlayer insulating layers 130 may include forming silicon oxide in order to wrap the bit line structures 120 on the active region 102, the field regions 103, and the gate structures 110 by performing a deposition process.

Forming the landing pad 140 may include forming a conductor vertically passing through the interlayer insulating layers 130 and in contact with the active region 102. For example, forming the landing pad 140 may include forming a silicide layer or a metal layer on the active region 102.

Forming the stopping insulating layer 150 may include forming a silicon nitride layer on the bit line structures 120, the interlayer insulating layers 130 and the landing pad 140 by performing a deposition process. For example, the stopping insulating layer 150 may include a material having a different etch selectivity from the interlayer insulating layer 130.

Forming the molding layer 160 may include forming a silicon oxide layer on the stopping insulating layer 150 by performing a deposition process. The molding layer 160 may include a material having a different etch selectivity from the stopping insulating layer 150.

Forming the silicon mask layer 510 may include forming polycrystalline silicon entirely on the molding layer 160 by a deposition process. The silicon mask layer 510 may include a material having a different etch selectivity from the molding layer 160.

Forming the first mask layer 520 may include forming a carbon-based material entirely on the silicon mask layer 510 by performing a deposition or coating process. The first mask layer 520 may include a material having a different etch selectivity from the silicon mask layer 510. For example, forming the first mask layer 520 may include forming an amorphous carbon layer (ACL) entirely on the silicon mask layer 510 by performing a CVD process. Furthermore, forming the first mask layer 520 may include forming a spin-on hard mask (SOH) entirely on the silicon mask layer 510 by performing a coating process.

Forming the second mask layer 530 may include forming an inorganic material entirely on the first mask layer 520 by performing a deposition process. The second mask layer 530 may include a material having a different etch selectivity from the first mask layer 520. For example, forming the second mask layer 530 may include forming one of silicon oxide (SiO₂), silicon nitride (Si₃N₄), and silicon oxynitride (SiON) entirely on the first mask layer 520 by performing a deposition process.

Forming the mask pattern 540a may include forming a material having a different etch selectivity from the second mask layer 530 on the second mask layer 530 by performing a deposition process, and forming a hole H selectively exposing the second mask layer 530 by performing a photolithography process. For example, the mask pattern 540a may include a photoresist.

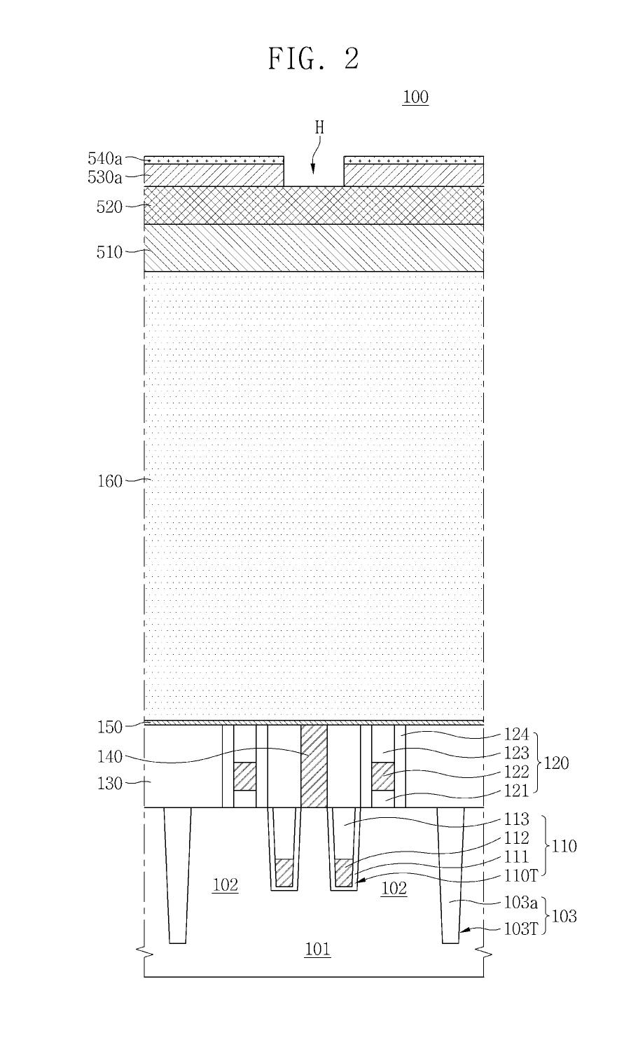

Referring to FIG. 2, the method may include selectively removing the second mask layer 530 using the mask pattern 540a as an etching mask. In this process, the second mask layer 530 may be patterned with a second mask pattern 530a, and the mask pattern 540a may become thinner. The first mask layer 520 may be exposed through the hole H.

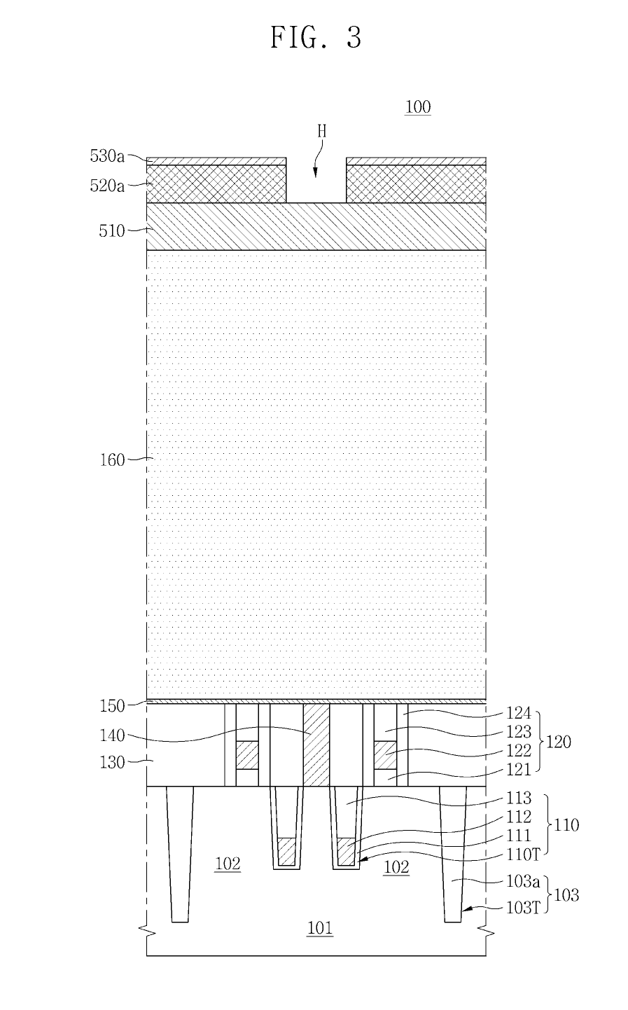

Referring to FIG. 3, the method may include selectively removing the first mask layer 520 using the mask pattern 540a and the second mask pattern 530a as etching masks. In this process, the first mask layer 520 may be patterned with a first mask pattern 520a, and the second mask pattern 530a may become thinner. In addition, all of the mask pattern 540a may be removed. The silicon mask layer 510 may be exposed through the hole H.

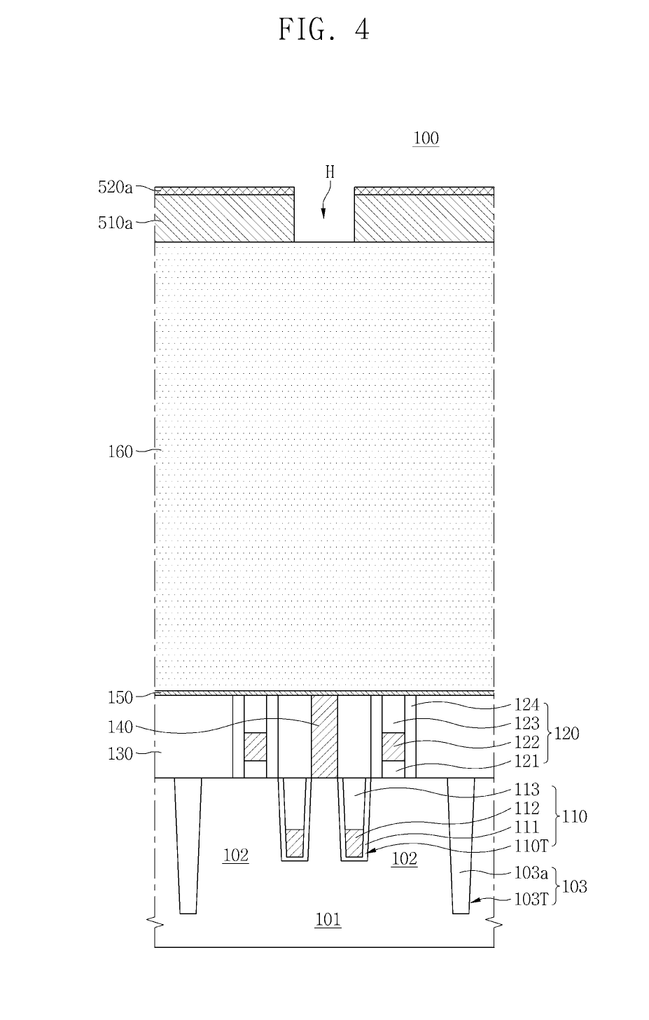

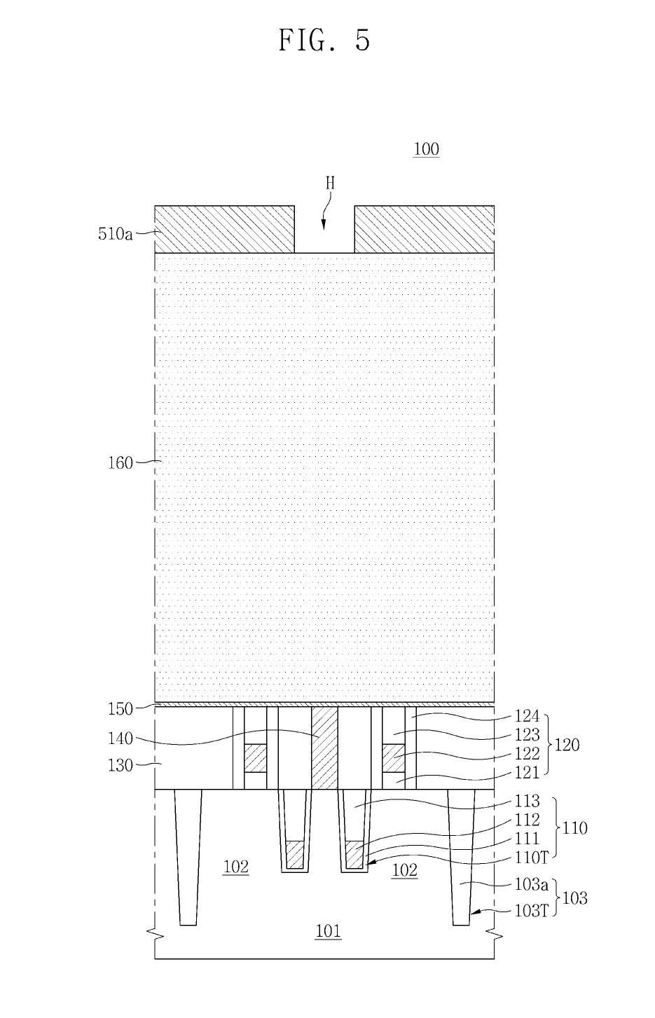

Referring to FIG. 4, the method may include selectively removing the silicon mask layer 510 using the second mask pattern 530a and the first mask pattern 520a as etching masks. In this process, the silicon mask layer 510 may be patterned with a silicon mask pattern 510a, and the first mask pattern 520a may become thinner. In addition, all of the second mask pattern 530a may be removed. The molding layer 160 may be exposed through the hole H.

Referring to FIG. 5, the method may include removing the thinned first mask pattern 520a by performing one or both of an etch-back and an ashing process.

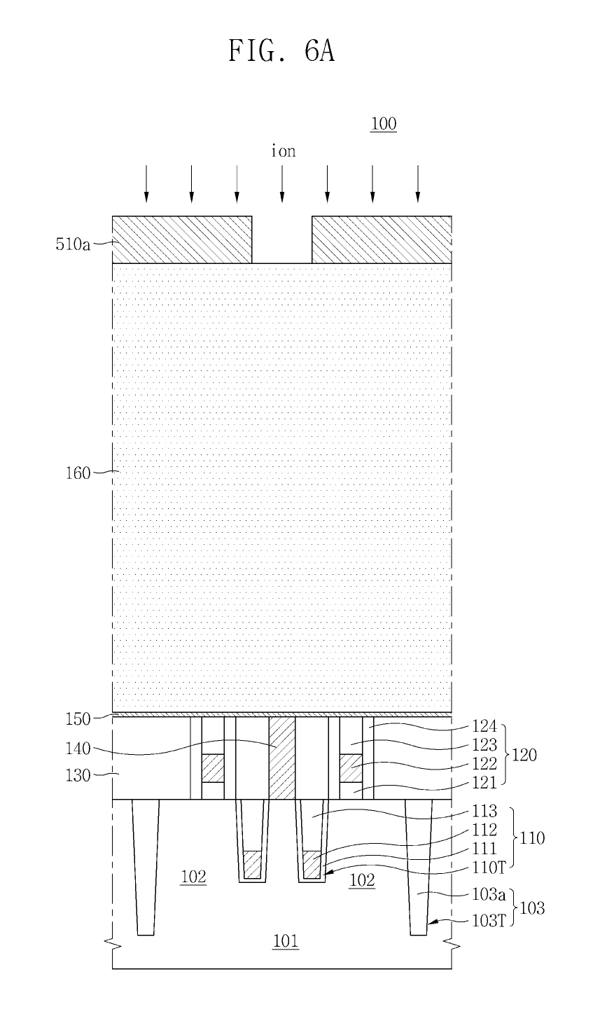

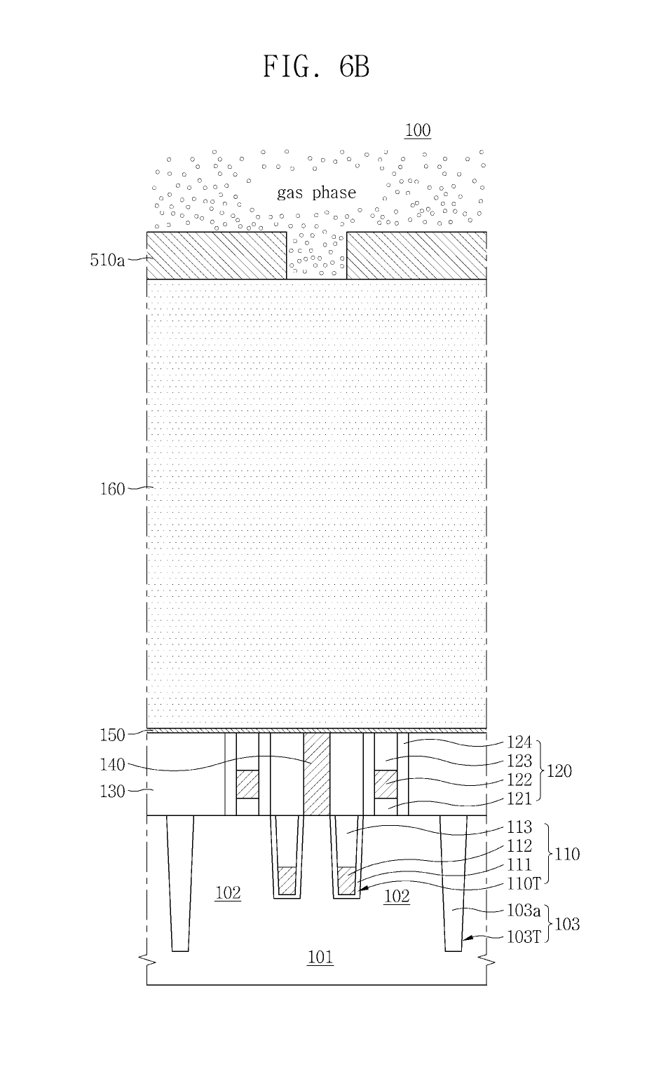

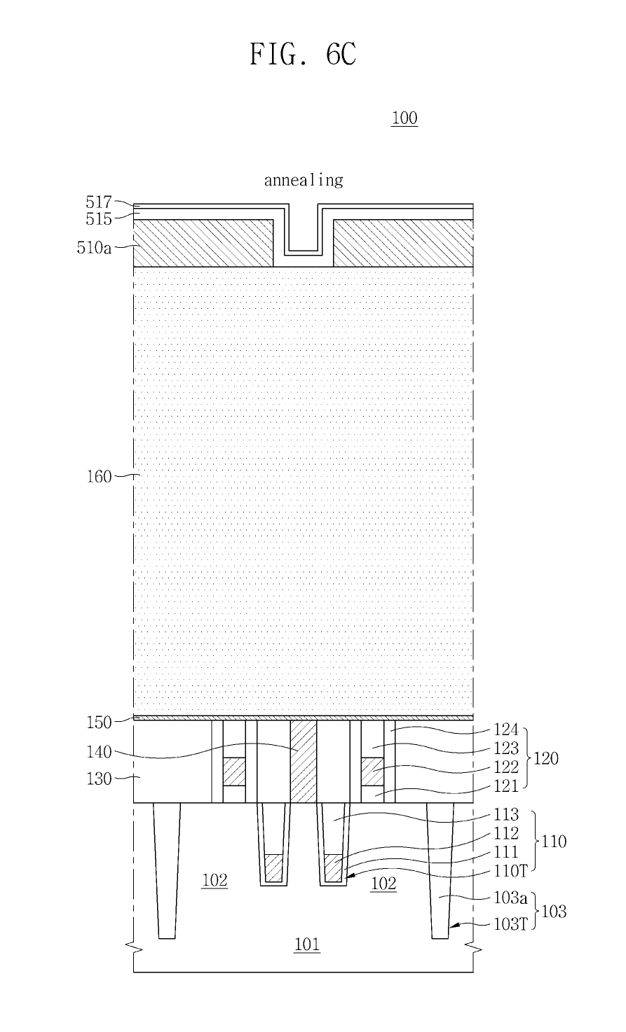

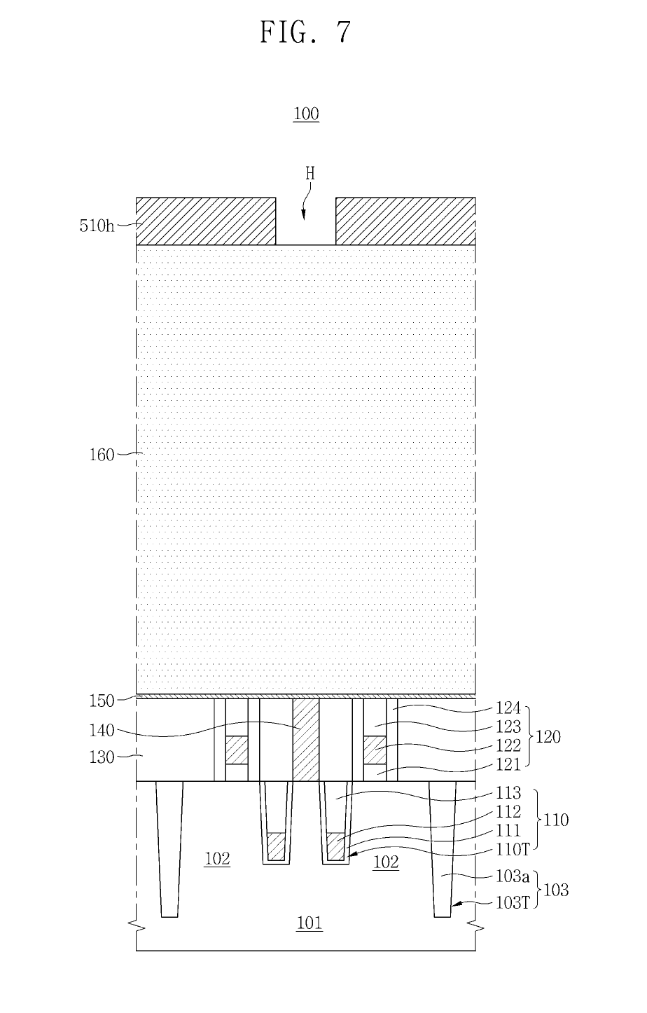

Referring to FIGS. 6A through 6C and 7, the method may include changing the silicon mask pattern 510a to a hard mask pattern 510h as described with reference to FIG. 7. Changing the silicon mask pattern 510a to the hard mask pattern 510h may include doping impurities into the silicon mask pattern 510a. For example, the impurities may include boron (B), argon (Ar), carbon (C), and phosphorus (P), but are not limited thereto.

Referring to FIG. 6A, doping the impurities into the silicon mask pattern 510a may include directly injecting the impurities into the silicon mask pattern 510a by performing an ion implantation process.

Referring to FIG. 6B, doping the impurities into the silicon mask pattern 510a may include performing an annealing process in a chamber in which gases including the impurities are injected. The annealing process may be performed at a temperature within a range of about 500° C. to 800° C. In this process, the impurities included in the gases may be doped into the silicon mask pattern 510a in a gas phase. For example, boron (B) may be doped into the silicon mask pattern 510a when diborane (B₂H₆) or boron trichloride (BCl₃) gas is used, and carbon (C) may be doped into the silicon mask pattern 510a when ethylene (C₂H₄) gas is used. Thus, when the impurities are doped into the silicon mask pattern 510a in a gas phase, the impurities may be doped into sides in the hole H as well as the top of the silicon mask pattern 510a.

Referring to FIG. 6C, doping the impurities into the silicon mask pattern 510a may include conformally forming a heterogeneous film 515 on surface of the silicon mask pattern 510a, and performing an annealing process. Forming the heterogeneous film 515 on the silicon mask pattern 510a may include forming one of boron silicate glass (BSG), phosphorus silicate glass (PSG), and arsenic silicate glass (ASG) on the surface of the silicon mask pattern 510a by performing a deposition process, such as CVD or ALD, but is not limited thereto. Performing the annealing process may include performing spike annealing at a temperature within a range of about 950° C. to 1050° C. Performing the spike annealing may prevent degradation of a semiconductor device 100 caused by a heat budget. Inter-diffusion of the impurities occurs between the silicon mask pattern 510a and the heterogeneous film 515 by performing the annealing process, and thus the impurities of the heterogeneous film 515 may be doped into the silicon mask pattern 510a.

Meanwhile, a method of doping the impurities using the heterogeneous film 515 may further include after forming the heterogeneous film 515 on the silicon mask pattern 510a, conformally forming a heterogeneous film capping layer 517 on the heterogeneous film 515. The heterogeneous film capping layer 517 may prevent emission of the impurities from the heterogeneous film 515 to the outside in the annealing process.

Referring to FIG. 7, a hard mask pattern 510h changed from the silicon mask pattern 510a may be formed as described with reference to FIGS. 6A through 6C. The hard mask pattern 510h may have a higher etch selectivity than the silicon mask pattern 510a. Etch selectivity of the hard mask pattern 510h may be varied based on types and concentrations of the impurities doped into the silicon mask pattern 510a. For example, the etch selectivity of the hard mask pattern 510h may be more improved in the case of doping carbon (C) than doping boron (B) as the impurities at the same concentrations of carbon (C) and boron (B). In addition, the etch selectivity of the hard mask pattern 510h may be improved according to an increase in the concentration of the impurities doped into the silicon mask pattern 510a. The concentration of the impurities may be at least about 2% or more of the silicon concentration of the silicon mask pattern 510a. When the concentration of the impurities is about 5%, the etch selectivity of the hard mask pattern 510h may be increased about 30%-50% more than etch selectivity of the silicon mask pattern 510a. For example, when the etch selectivity of the silicon mask pattern 510a is 6:1 and boron (B) corresponding to about 5% of the silicon concentration of the silicon mask pattern 510a is doped into the silicon mask pattern 510a, the silicon mask pattern 510a may be changed to the hard mask pattern 510h in which etch selectivity is improved to about 7.8:1. In addition, when carbon (C) corresponding to about 5% of the silicon concentration of the silicon mask pattern 510a is doped into the silicon mask pattern 610a, the silicon mask pattern 510a may be changed to the hard mask pattern 510h in which etch selectivity is improved to about 9:1.

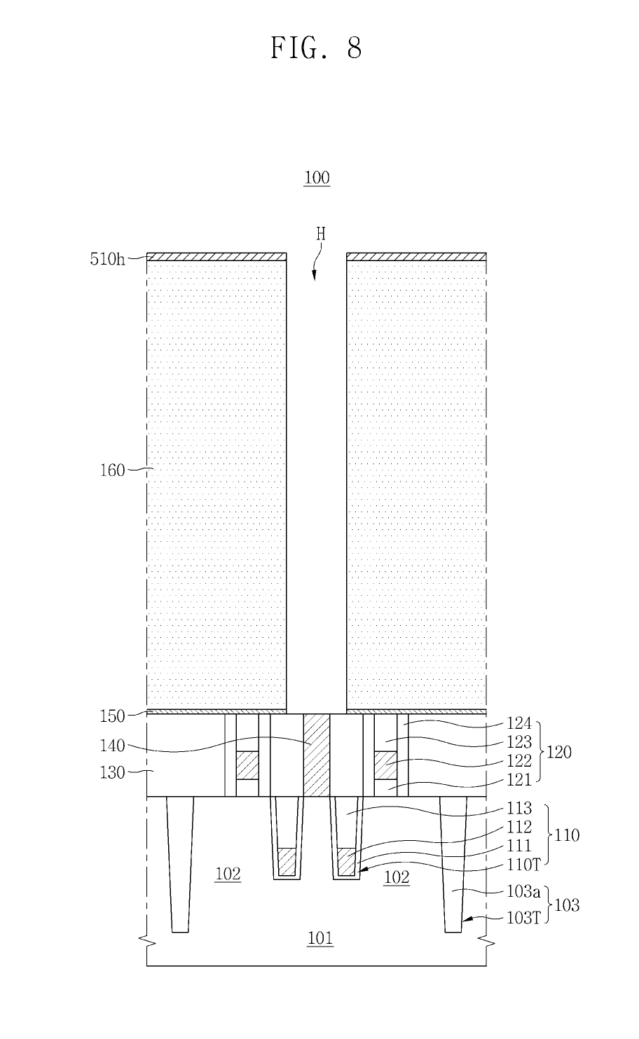

Referring to FIG. 8, the method may include selectively removing the molding layer 160 and the stopping insulating layer 150 using the hard mask pattern 510h as an etching mask. In this process, the hole H having a high aspect ratio contact (HARC) structure may be formed, and the hard mask pattern 510h may become thinner. The landing pad 140 may be exposed through the hole H.

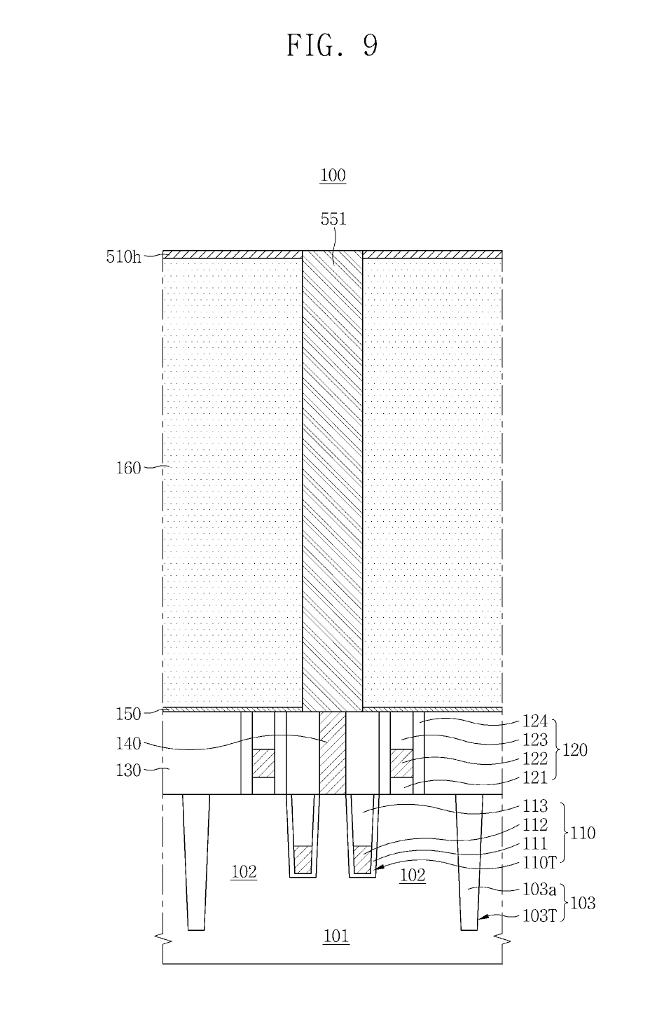

Referring to FIG. 9, the method may include filling a first sacrificial layer 551 in the hole H. The first sacrificial layer 551 may include a material having a different etch selectivity from the molding layer 160 and the stopping insulating layer 150. For example, the first sacrificial layer 551 may include organic matters, such as a resist, a photoresist, an organic resin, or an organic polymer, but is not limited thereto.

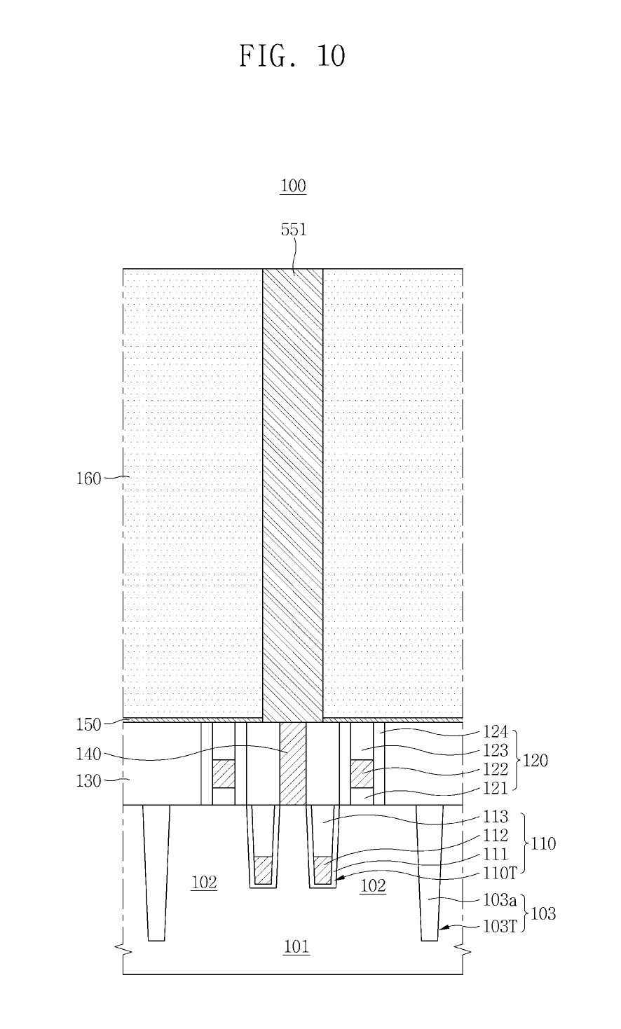

Referring to FIG. 10, the method may include removing the thinned hard mask pattern 510h. Removing the hard mask pattern 510h may include performing a wet etching process using an etchant including ammonia water. Furthermore, removing the hard mask pattern 510h may include exposing the molding layer 160 by performing a planarization process, such as CMP, but is not limited thereto.

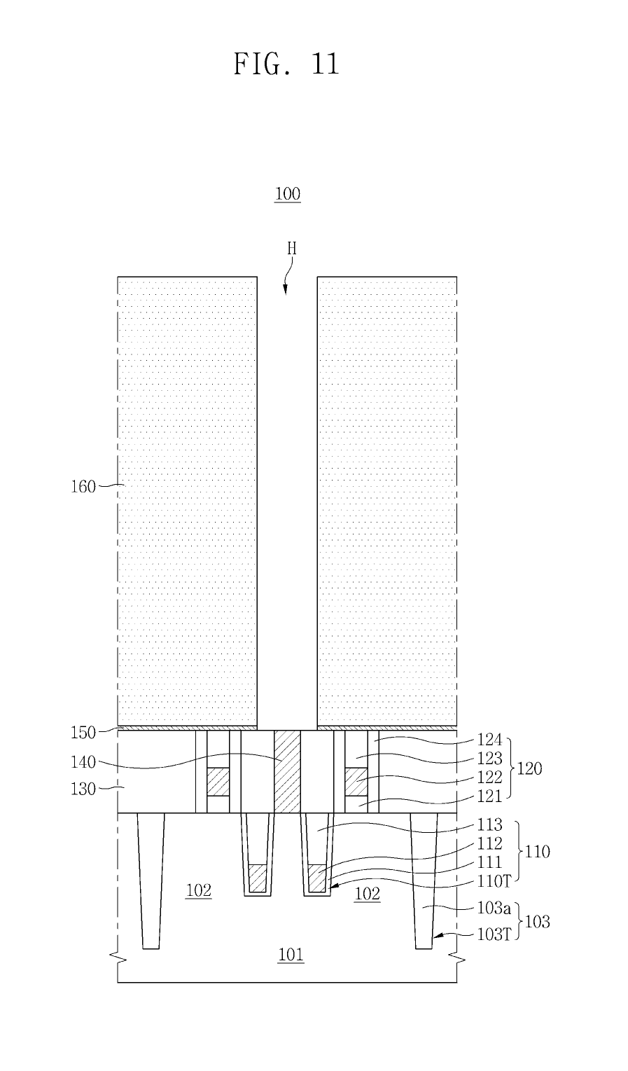

Referring to FIG. 11, the method may include removing the first sacrificial layer 551. Removing the first sacrificial layer 551 may include performing an ashing process using oxygen (O₂) gas.

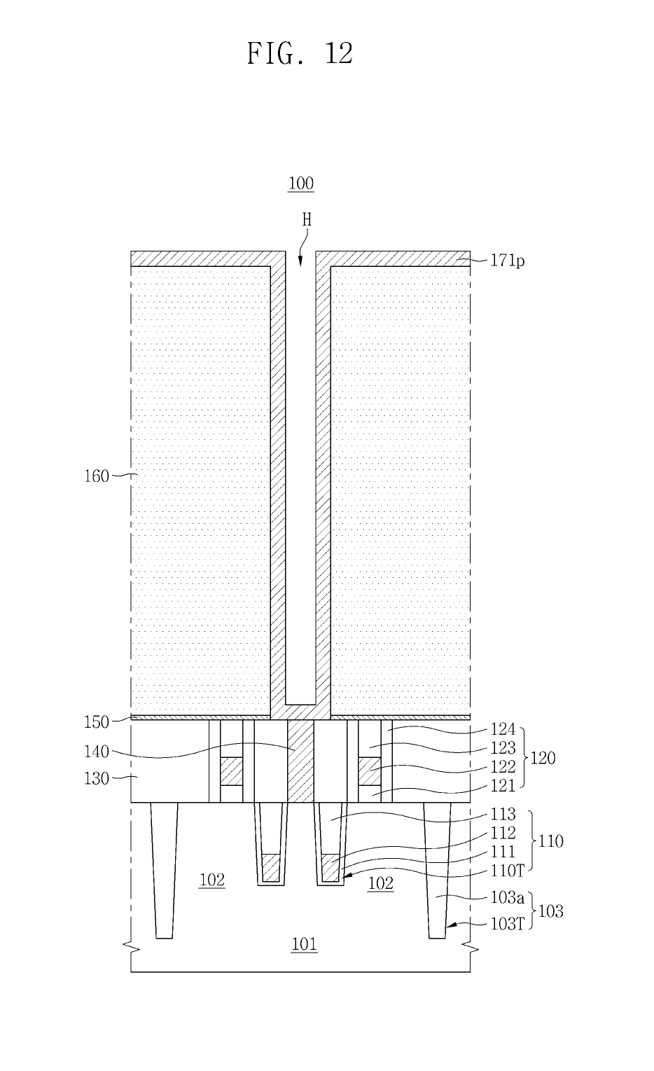

Referring to FIG. 12, the method may include forming a preliminary storage electrode 171p in the hole H. Forming the preliminary storage electrode 171p may include conformally forming a silicide, a metal, or a metal compound on the inner walls of the hole H, but is not limited thereto.

Referring to FIG. 13, the method may include filling a second sacrificial layer 552 in the hole H. The second sacrificial layer 552 may include a material having a different etch selectivity from the molding layer 160 and the preliminary storage electrode 171p. For example, the second sacrificial layer 552 may include organic matters such as a resist, a photoresist, an organic resin, or an organic polymer, but is not limited thereto.

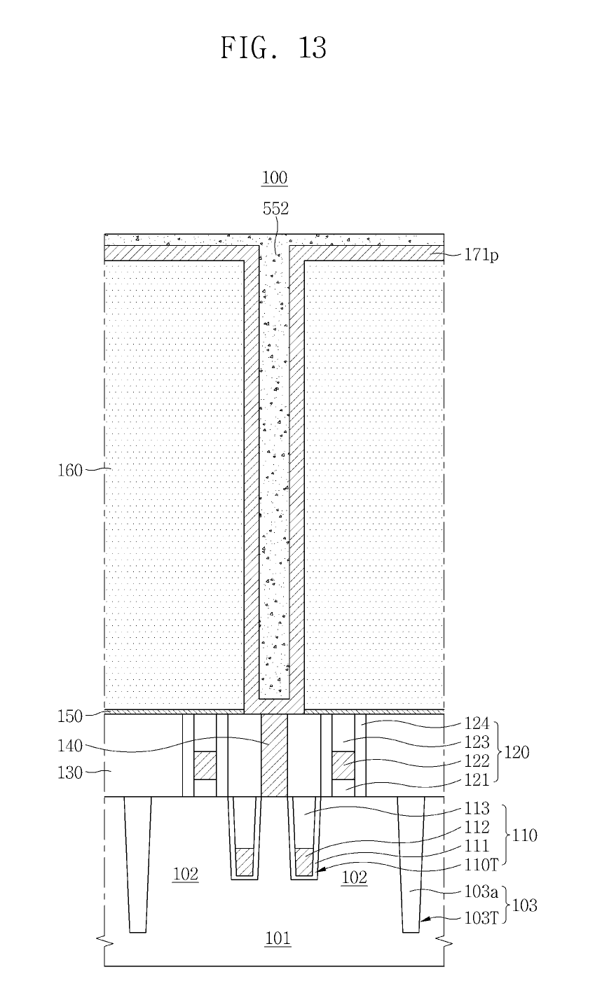

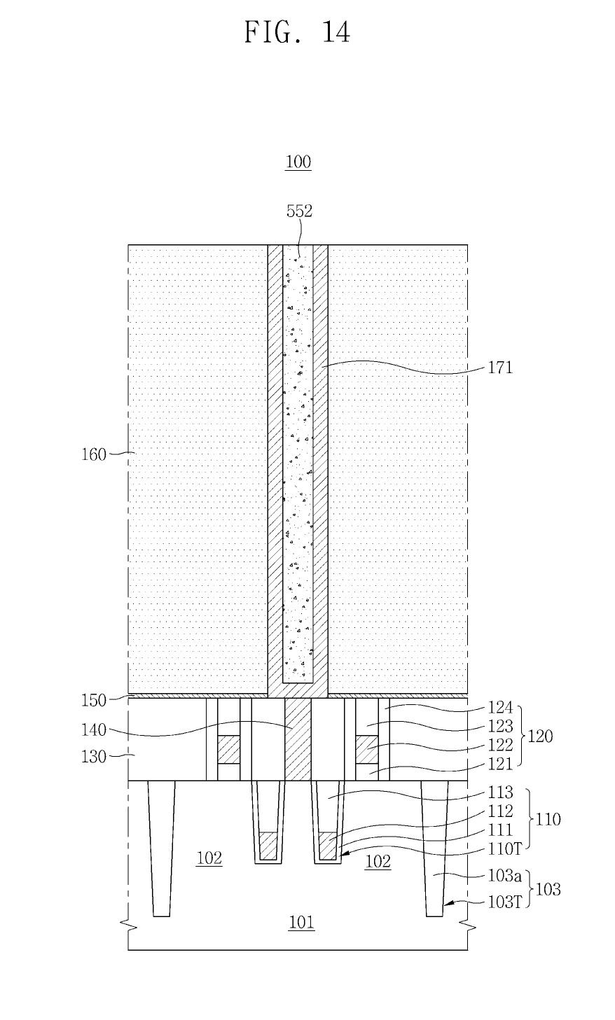

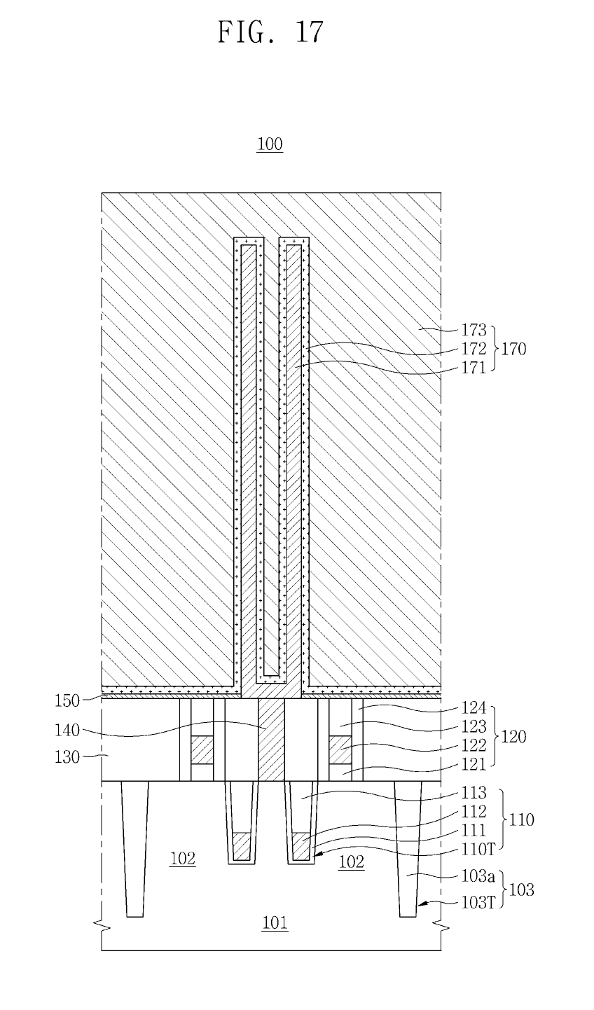

Referring to FIG. 14, the method may include removing the preliminary storage electrode 171p on the top surface of the molding layer 160 by performing a planarization process, such as CMP, but is not limited thereto. In this process, the preliminary storage electrode 171p may be divided into individual storage electrodes 171. The storage electrodes 171 may be used as lower electrodes of a capacitor structure 170 illustrated in FIG. 17, which will be described later.

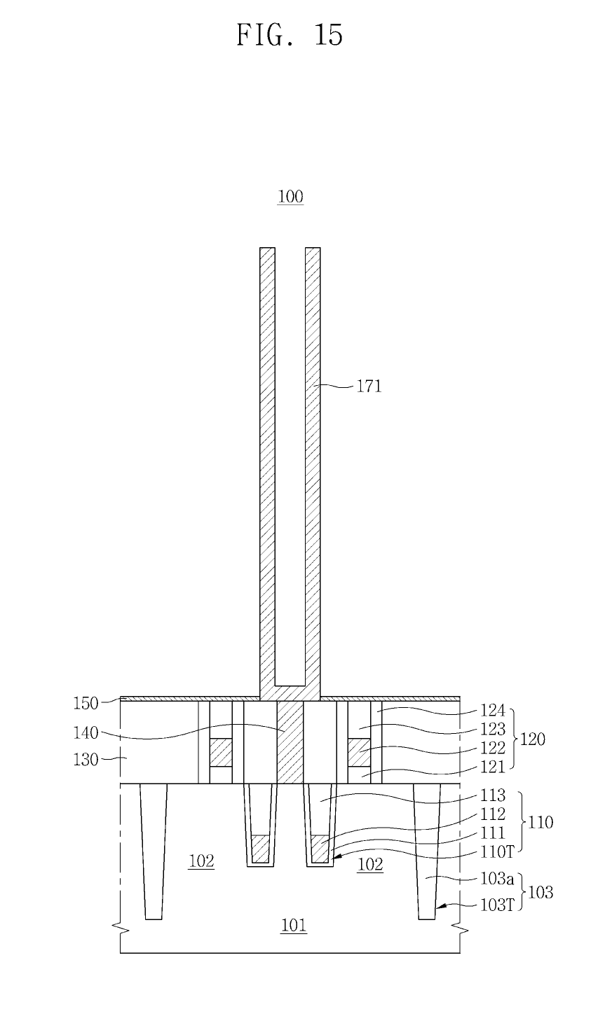

Referring to FIG. 15, the method may include removing the second sacrificial layer 552 and the molding layer 160. Removing the second sacrificial layer 552 may include performing an ashing process using oxygen (O₂) gas. Removing the molding layer 160 may include performing a wet etching process using an etchant including hydrogen peroxide. In this process, the storage electrodes 171 may be exposed.

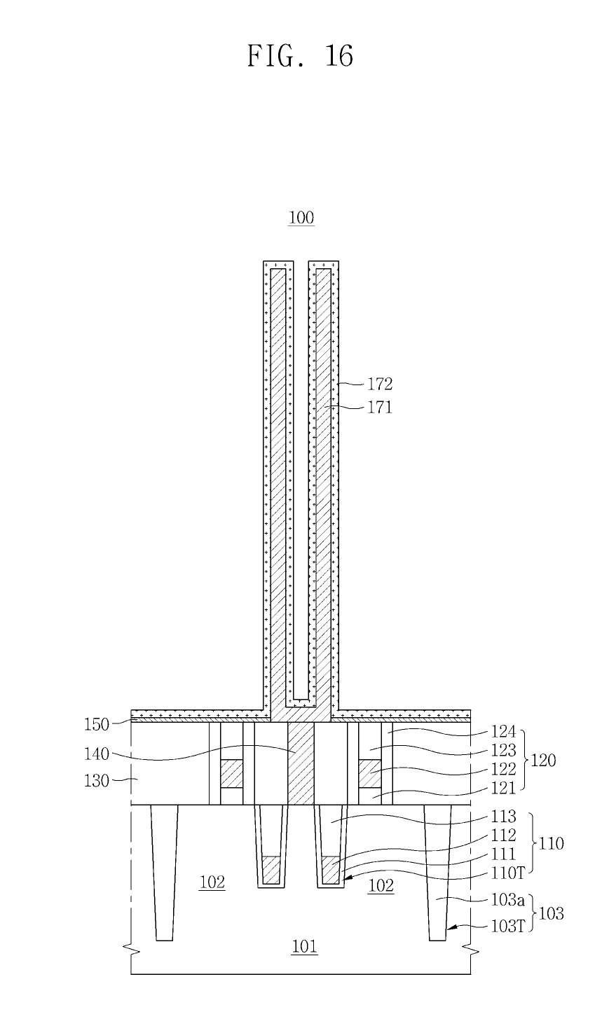

Referring to FIG. 16, the method may include conformally forming a capacitor dielectric layer 172 on surfaces of the storage electrodes 171 and the stopping insulating layer 150.

Referring to FIG. 17, the method may include forming an upper electrode 173 on the capacitor dielectric layer 172. Forming the upper electrode 173 may include forming a metal layer, such as titanium nitride (TiN), but is not limited thereto, on the capacitor dielectric layer 172. In this process, a capacitor structure 170 including the storage electrodes 171, the capacitor dielectric layer 172, and the upper electrode 173 may be formed.

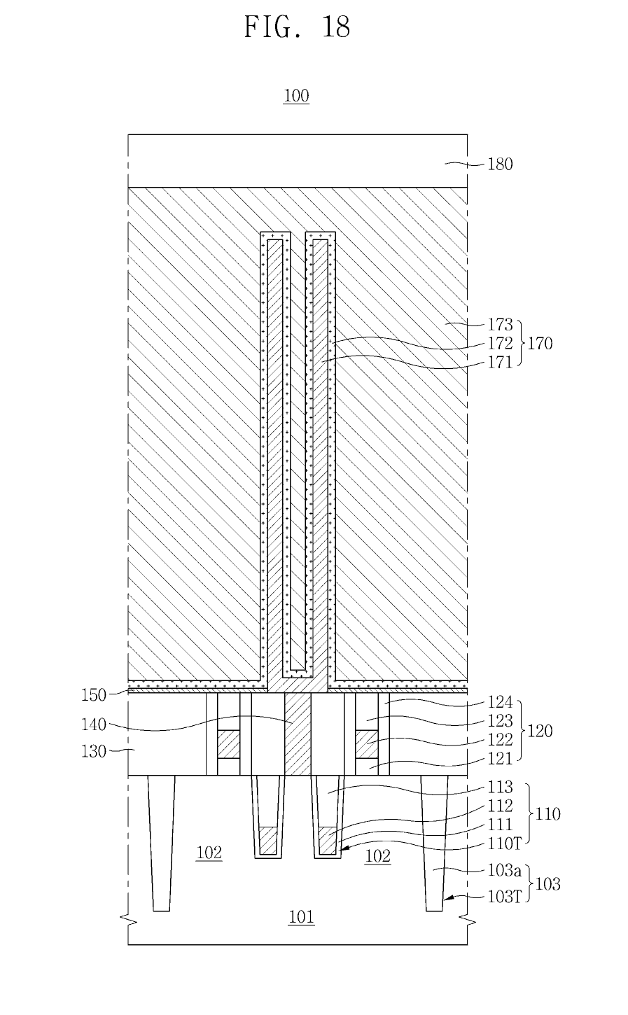

Referring to FIG. 18, the method may include forming a cell capping insulating layer 180 on the surface of the upper electrode 173 in order to cover the capacitor structure 170. The cell capping insulating layer 180 may include silicon oxide.

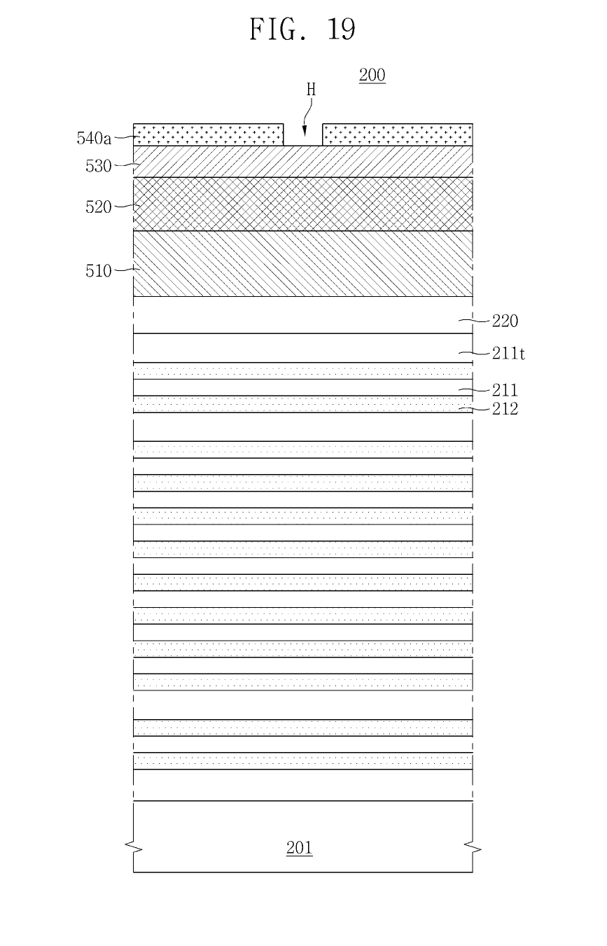

FIGS. 19 through 37 are longitudinal sectional views describing a method of fabricating a semiconductor device 200 in accordance with an exemplary embodiment of the present general inventive concept. The semiconductor device 200 may include a semiconductor device having a vertical channel.

Referring to FIG. 19, a method of fabricating a semiconductor device 200 may include alternatively and repeatedly forming a plurality of first insulating layers 211 and 211t, and a plurality of second insulating layers 212 on a substrate 201, forming a first capping layer 220 on the uppermost first insulating layer 211t, forming a silicon mask layer 510 on the first capping layer 220, forming a first mask layer 520 on the silicon mask layer 510, forming a second mask layer 530 on the first mask layer 520, and forming a mask pattern 540a on the second mask layer 530.

Here, the substrate 201 may include a single crystal silicon wafer, an SOI wafer, and a silicon germanium wafer, but is not limited thereto.

Forming the plurality of first insulating layers 211 and 211t may include forming silicon oxide layers by performing a deposition process. Forming the plurality of second insulating layers 212 may include forming silicon nitride layers by performing a deposition process.

Forming the first capping layer 220 may include forming an insulating material layer by performing a deposition process. The insulating material layer may include silicon oxide as an example.

Forming the silicon mask layer 510 may include forming polycrystalline silicon entirely on the first capping layer 220 by performing a deposition process. The silicon mask layer 510 may have a different etch selectivity from the first capping layer 220.

Forming the first mask layer 520 may include forming a carbon-based material entirely on the silicon mask layer 510 by performing a deposition or a coating process. The first mask layer 520 may have a material having a different etch selectivity from the silicon mask layer 510. For example, forming the first mask layer 520 may include forming an amorphous carbon layer (ACL) entirely on the silicon mask layer 510 by performing a CVD process. Furthermore, forming the first mask layer 520 may include forming an SOH entirely on the silicon mask layer 510 by performing a coating process.

Forming the second mask layer 530 may include forming an inorganic material entirely on the first mask layer 520 by performing a deposition process. The second mask layer 530 may include a material having a different etch selectivity from the first mask layer 520. For example, forming the second mask layer 530 may include forming one of silicon oxide (SiO₂), silicon nitride (Si₃N₄), and silicon oxynitride (SiON) entirely on the first mask layer 520 by performing a deposition process.

Forming the mask pattern 540a may include forming a material having a different etch selectivity from the second mask layer 530 on the second mask layer 530 by performing a deposition process, and forming a hole H selectively exposing the second mask layer 530 by performing a photolithography process. For example, the mask pattern 540a may include a photoresist.

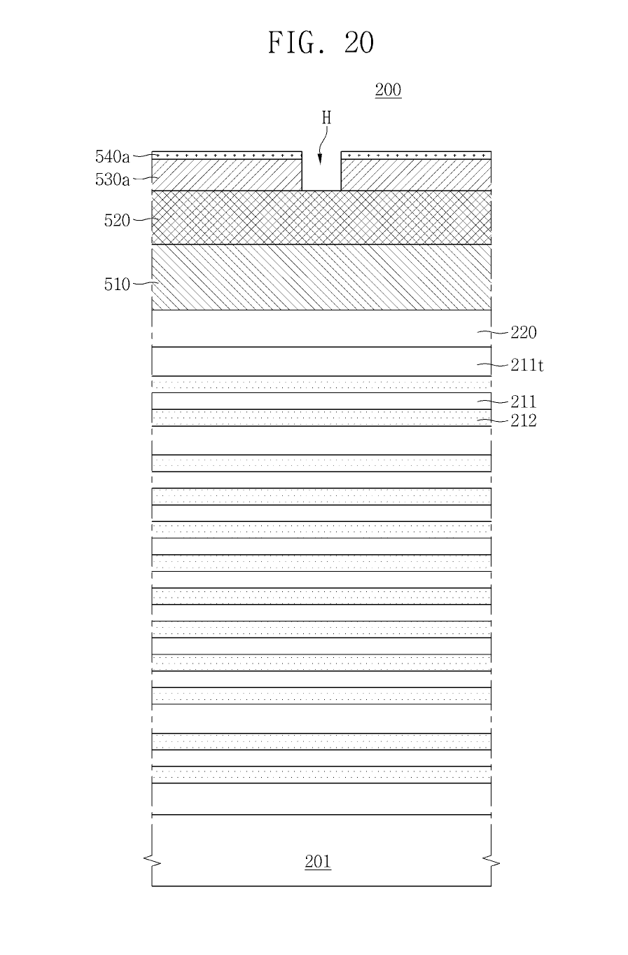

Referring to FIG. 20, the method may include selectively removing the second mask layer 530 using the mask pattern 540a as an etching mask. In this process, the second mask layer 530 may be patterned with a second mask pattern 530a and the mask pattern 540a may become thinner. The first mask layer 520 may be exposed through the hole H.

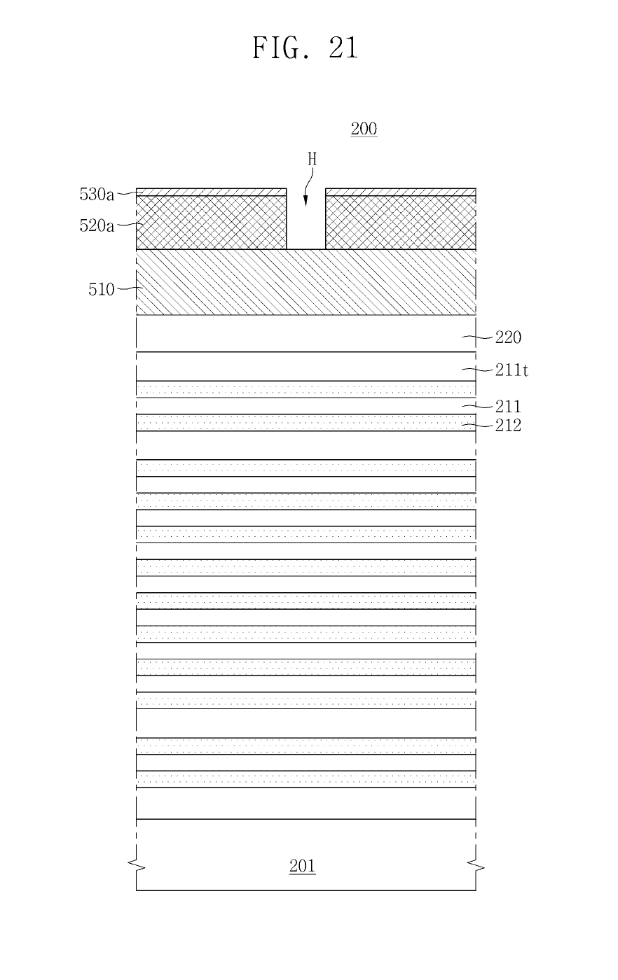

Referring to FIG. 21, the method may include selectively removing the first mask layer 520 using the mask pattern 540a and the second mask pattern 530a as etching masks. In this process, the first mask layer 520 may be patterned with a first mask pattern 520a, and the second mask pattern 530a may become thinner. In addition, all of the mask pattern 540a may be removed. The silicon mask layer 510 may be exposed through the hole H.

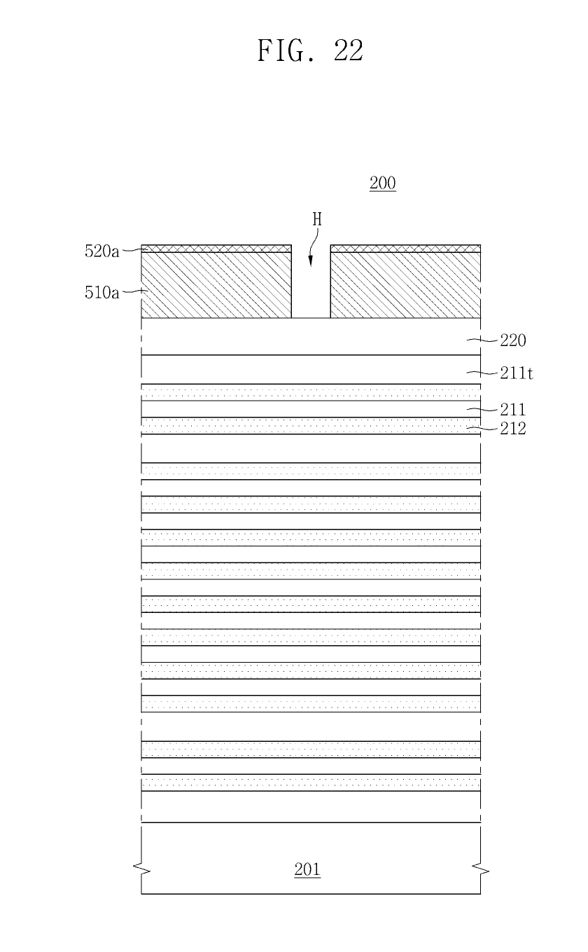

Referring to FIG. 22, the method may include selectively removing the silicon mask layer 510 using the second mask pattern 530a and the first mask pattern 520a as etching masks. In this process, the silicon mask layer 510 may be patterned with a silicon mask pattern 510a, and the first mask pattern 520a may become thinner. In addition, all of the second mask pattern 530a may be removed. The first capping layer 220 may be exposed through the hole H.

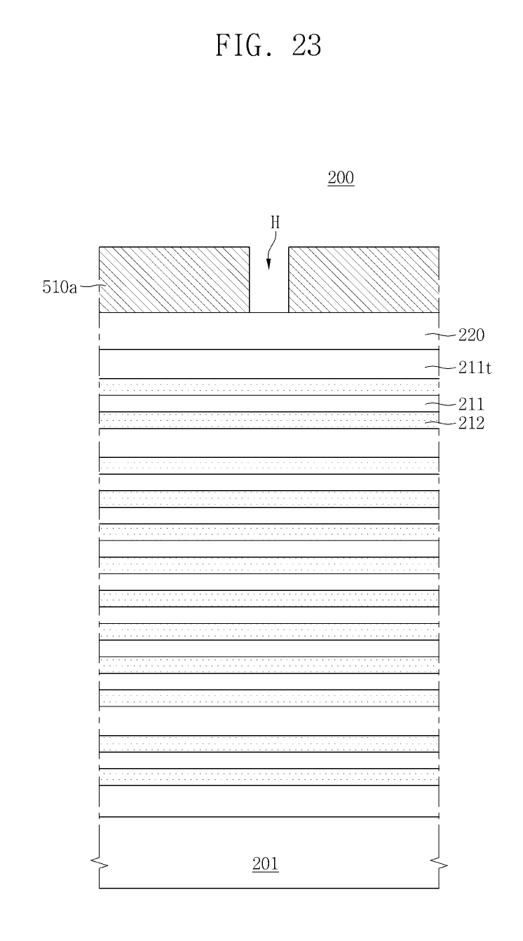

Referring to FIG. 23, the method may include removing the thinned first mask pattern 520a by performing an etch-back and/or ashing process.

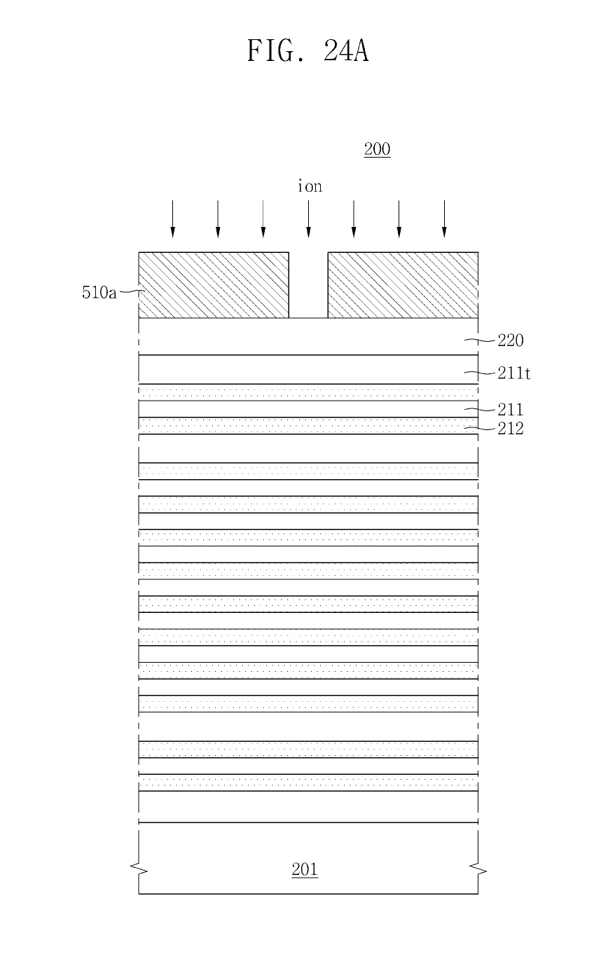

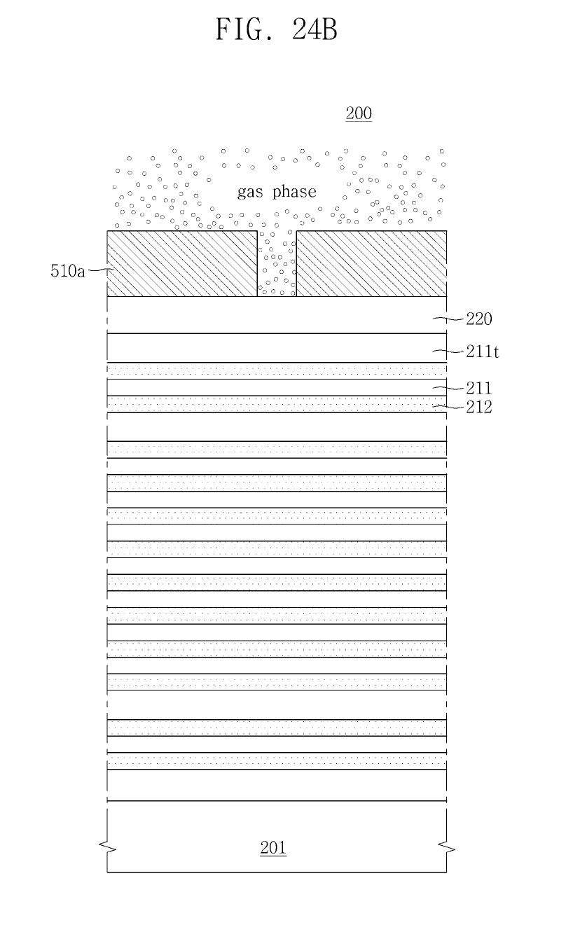

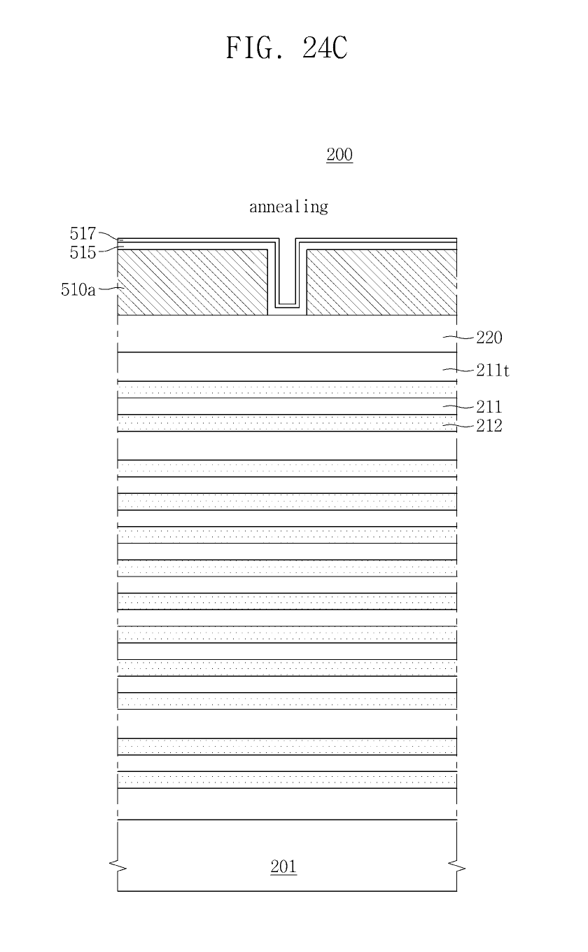

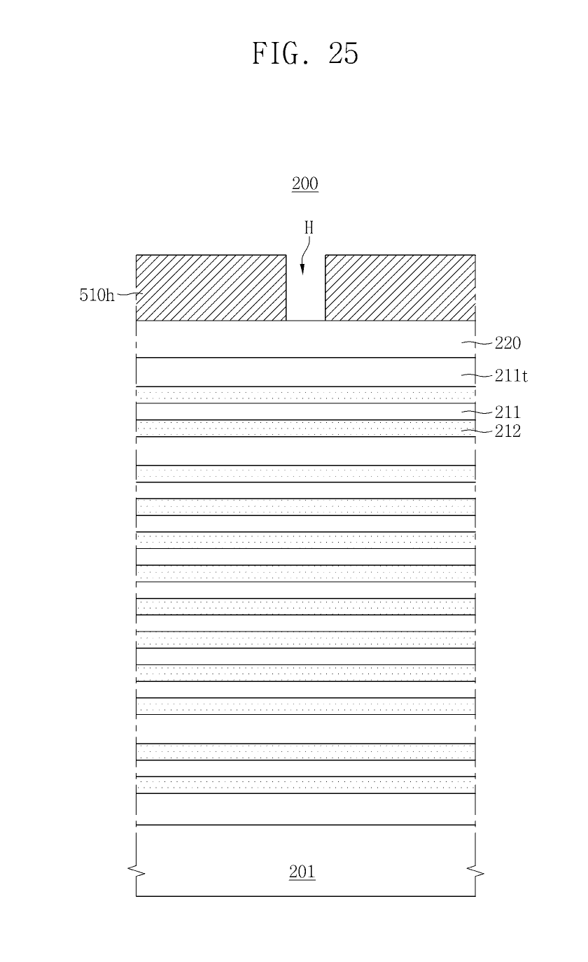

Referring to FIGS. 24A through 24C and 25, the method may include changing the silicon mask pattern 510a to a hard mask pattern 510h as described with reference to FIG. 25. Changing the silicon mask pattern 510a to the hard mask pattern 510h may include doping impurities into the silicon mask pattern 510a. For example, the impurities may include boron (B), argon (Ar), carbon (C), and phosphorus (P).

Referring to FIG. 24A, doping the impurities into the silicon mask pattern 510a may include directly injecting the impurities into the silicon mask pattern 510a by performing an ion implantation process.

Referring to FIG. 24B, doping the impurities into the silicon mask pattern 510a may include performing an annealing process in a chamber in which gases including the impurities are injected. The annealing process may be performed at a temperature within a range of about 500° C. to 800° C. In this process, the impurities included in the gases may be doped into the silicon mask pattern 510a in a gas phase. For example, boron (B) may be doped into the silicon mask pattern 510a when diborane (B₂H₆) or boron trichloride (BCl₃) gas is used, and carbon (C) may be doped into the silicon mask pattern 510a when ethylene (C₂H₄) gas is used. Thus, when the impurities are doped into the silicon mask pattern 510a in a gas phase, the impurities may be doped into sides of the hole H as well as the top of the silicon mask pattern 510a.

Referring to FIG. 24C, doping the impurities into the silicon mask pattern 510a may include conformally forming a heterogeneous film 515 on the surface of the silicon mask pattern 510a, and performing an annealing process. Forming the heterogeneous film on the silicon mask pattern 510a may include forming one of BSG, PSG, and ASG on the surface of the silicon mask pattern 510a by performing a deposition process, such as CVD or ALD, but is not limited thereto. Performing the annealing process may include performing spike annealing at a temperature within a range of about 950° C. to 1050° C. Performing the spike annealing may prevent degradation of the semiconductor device 200 caused by a heat budget. Inter-diffusion of the impurities occurs between the silicon mask pattern 510a and the heterogeneous film 515 when the annealing process is performed, and thus the impurities of the heterogeneous film 515 may be doped into the silicon mask pattern 510a.

Meanwhile, the method of doping impurities using the heterogeneous film 515 may further include after forming the heterogeneous film 515 on the silicon mask pattern 510a, conformally forming a heterogeneous film capping layer 517 on the heterogeneous film 515. The heterogeneous film capping layer 517 may be prevented emission of the impurities from the heterogeneous film 515 to the outside in the annealing process.

Referring to FIG. 25, a hard mask pattern 510h changed from the silicon mask pattern 510a may be formed as described with reference to FIGS. 24A through 24C. The hard mask pattern 510h may have a higher etch selectivity than the silicon mask pattern 510a. Etch selectivity of the hard mask pattern 510h may be varied based on types and concentrations of the impurities doped into the silicon mask pattern 510a. For example, the etch selectivity of the hard mask pattern 510h may be more improved in the case of doping carbon (C) than doping boron (B) as the impurities at the same concentrations of carbon (C) and boron (B). In addition, the etch selectivity of the hard mask pattern 510h may be improved according to increasing concentration of the impurities doped into the silicon mask pattern 510a. The concentration of the impurities may be at least about 2% or more of the silicon concentration of the silicon mask pattern 510a. When the concentration of the impurities is about 5%, the etch selectivity of the hard mask pattern 510h may be increased about 30%-50% more than etch selectivity of the silicon mask pattern 510a. For example, when the etch selectivity of the silicon mask pattern 510a is 6:1, and boron (B) corresponding to about 5% of the silicon concentration of the silicon mask pattern 510a is doped into the silicon mask pattern 510a, the silicon mask pattern 510a may be changed to the hard mask pattern 510h in which etch selectivity is improved to about 7.8:1. In addition, when carbon (C) corresponding to about 5% of the silicon concentration of the silicon mask pattern 510a is doped into the silicon mask pattern 610a, the silicon mask pattern 510a may be changed to the hard mask pattern 510h in which etch selectivity is improved to about 9:1.

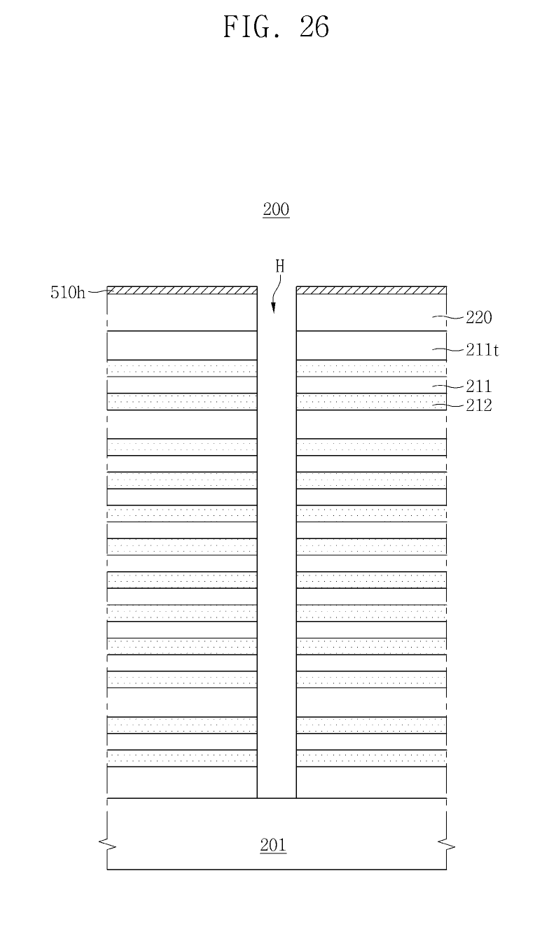

Referring to FIG. 26, the method may include selectively removing the first capping layer 220, the plurality of first insulating layers 211 and 211t, and the plurality of second insulating layers 212 using the hard mask pattern 510h as an etching mask. In this process, the hole H having an HARC structure may be formed, and the hard mask pattern 510h may become thinner. The substrate 201 may be exposed in the hole H.

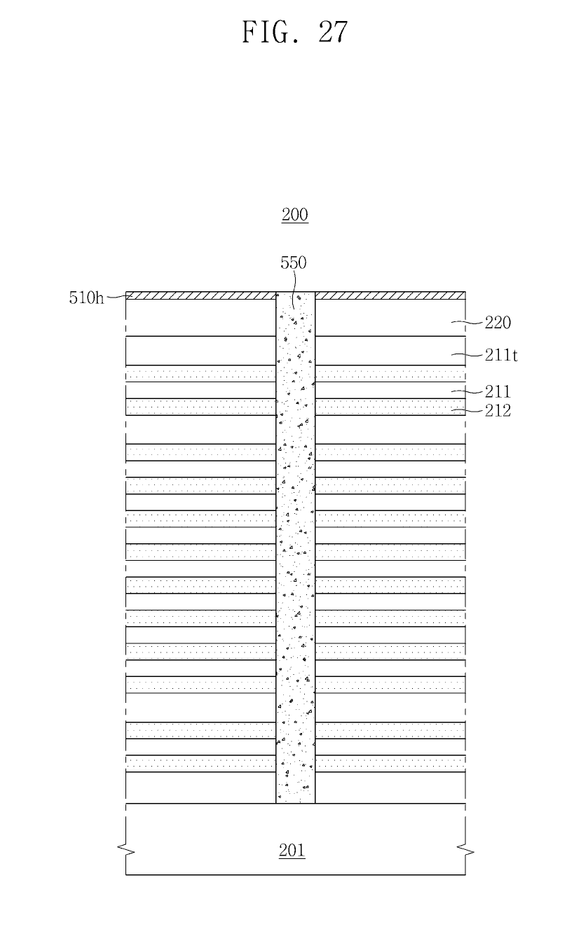

Referring to FIG. 27, the method may include filling a sacrificial layer 550 in the hole H. The sacrificial layer 550 may include a material having a different etch selectivity from the plurality of first insulating layers 211 and 211t, the plurality of second insulating layers 212, and the first capping layer 220. For example, the sacrificial layer 550 may include organic matters such as a resist, a photoresist, an organic resin, or an organic polymer, but is not limited thereto.

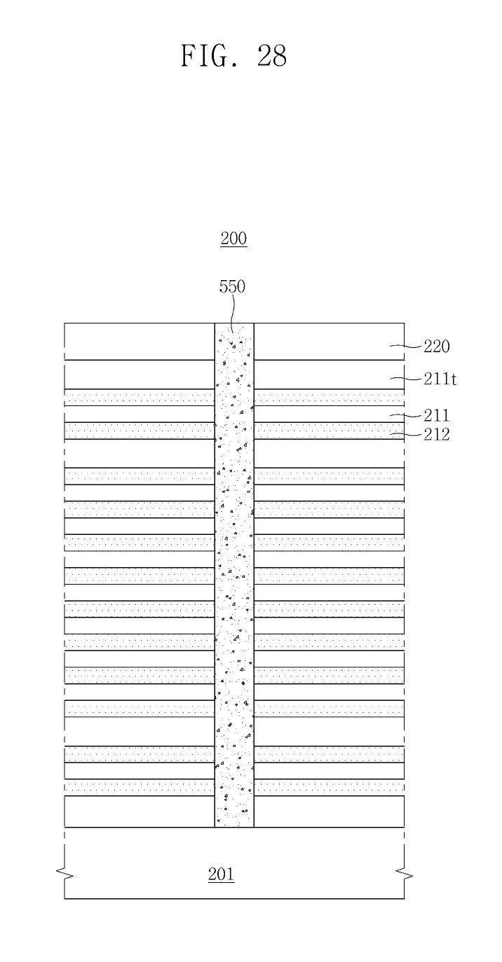

Referring to FIG. 28, the method may include removing the thinned hard mask pattern 510h. Removing the hard mask pattern 510h may include performing a wet etching process using an etchant including ammonia water. Furthermore, removing the hard mask pattern 510h may include exposing the first capping layer 220 by performing a planarization process, such as CMP, but is not limited thereto.

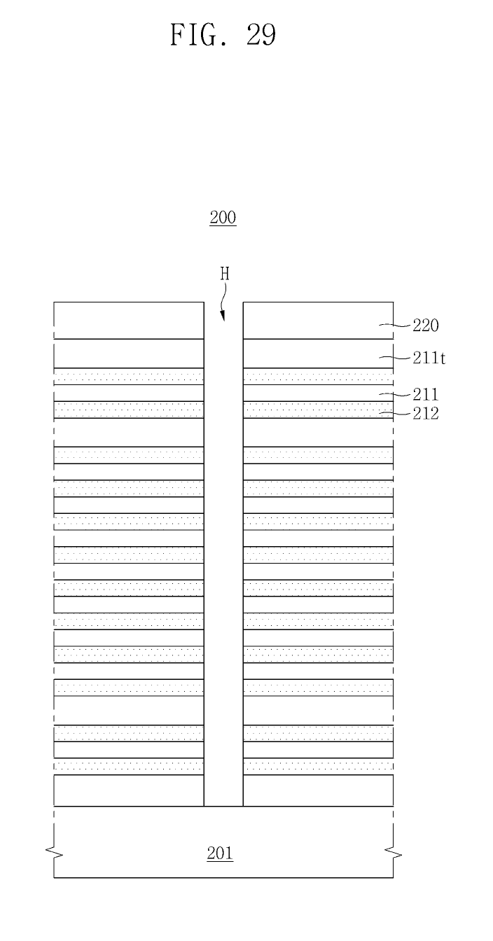

Referring to FIG. 29, the method may include removing the sacrificial layer 550. Removing the sacrificial layer 550 may include performing an ashing process using oxygen (O₂) gas.

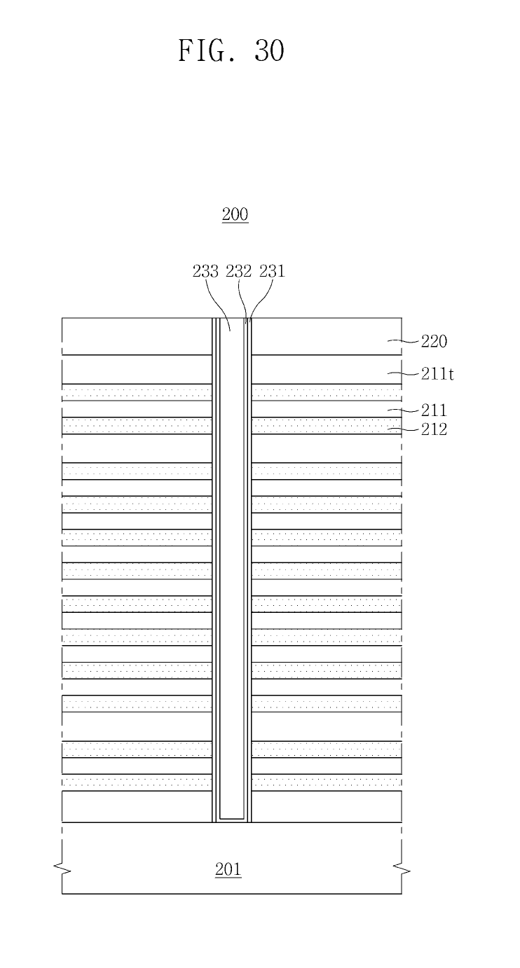

Referring to FIG. 30, the method may include forming a dielectric layer 231, a channel active layer 232, and a channel core layer 233 in the hole H. Forming the dielectric layer 231 may include conformally forming the dielectric layer 231 on inner walls of the hole H, and exposing the first capping layer 220 and surface of a substrate 201 on bottom of the hole H by performing an etch-back process. In this process, the dielectric layer 231 may be formed in a multi-layer structure, and conformally formed only on inner walls of the hole H. Forming the channel active layer 232 may include conformally forming a polysilicon layer or a single crystal silicon layer on the first capping layer 220 and in the hole H by performing a deposition process. Forming the channel core layer 233 may include forming silicon oxide on the channel active layer 232 in order to fill the inside of the hole H. Then, the method may further include exposing the first capping layer 220 by performing a planarization process, such as CMP, but is not limited thereto.

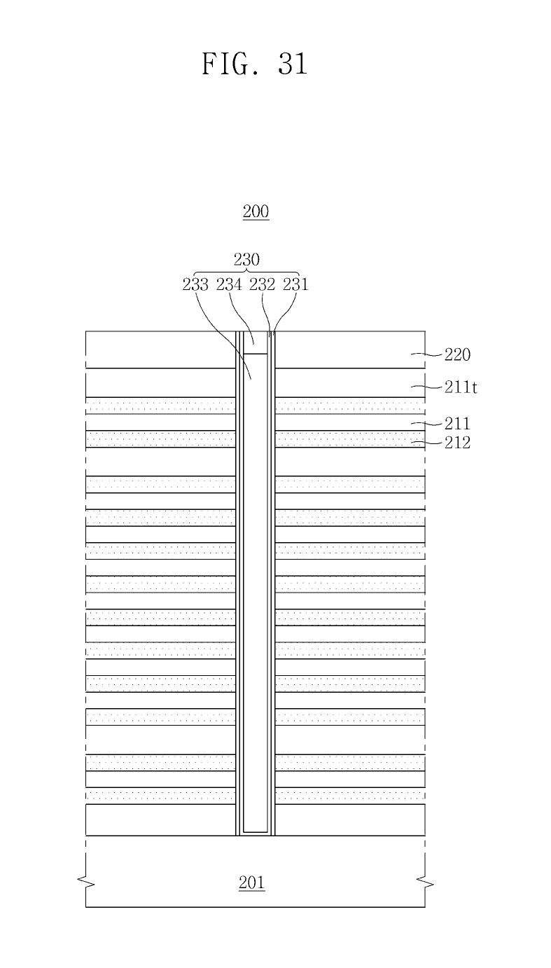

Referring to FIG. 31, the method may include forming a channel pad layer 234 contacted to the channel active layer 232. Forming the channel pad layer 234 may include recessing the top of the channel core layer 233 by performing an etch-back process, and forming a polysilicon layer or a single crystal silicon layer in the recessed space by performing a deposition process. In this process, a channel structure 230 including the dielectric layer 231, the channel active layer 232, the channel core layer 233, and the channel pad layer 234 may be formed.

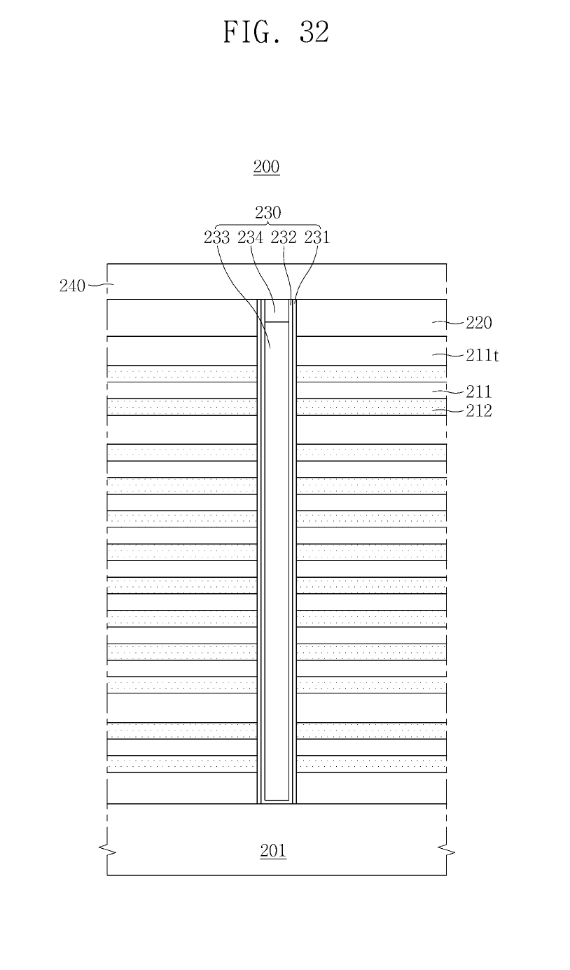

Referring to FIG. 32, the method may include forming a second capping layer 240 on the first capping layer 220 and the channel structure 230. Forming the second capping layer 240 may include forming silicon oxide on the first capping layer 220 and the channel structure 230 by performing a deposition process.

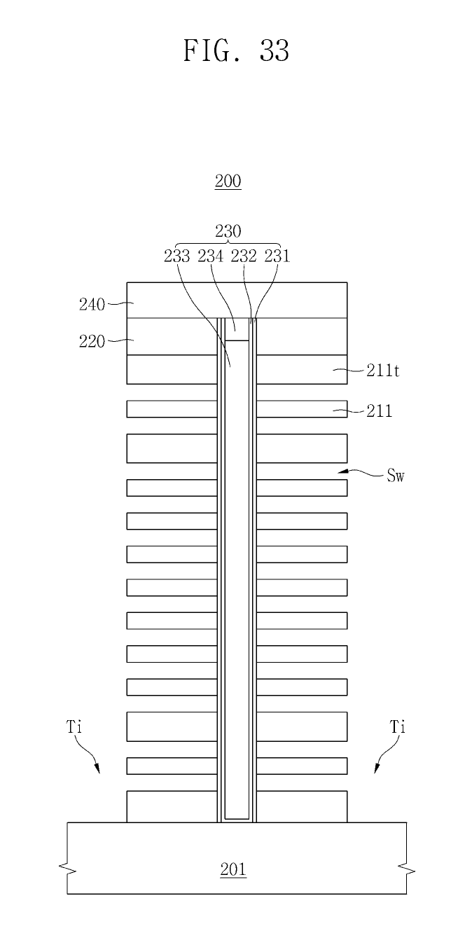

Referring to FIG. 33, the method may include, forming element isolation trenches Ti vertically passing through the plurality of first insulating layers 211 and 211t, the plurality of second insulating layers 212, the first capping layer 220, and the second capping layer 240 and in contact with the substrate 201 by performing an etching process, and forming word line spaces Sw by removing the plurality of second insulating layers 212 through the element isolation trenches Ti.

Referring to FIG. 34, the method may include forming a plurality of word lines 215 in the word line spaces Sw. Forming the plurality of word lines 215 may include conformally forming blocking layers 215a on the second capping layer 240, on inner walls of the element isolation trench Ti, and in the word line spaces Sw by performing a deposition process, and forming word line electrode layers 215b on the blocking layers 215a in order to fill the word line spaces Sw by performing a deposition process. For example, the blocking layers 215a may include aluminum oxide, and the word line electrode layers 215b may include a metal, such as tungsten (W), but is not limited thereto. The method may include removing the blocking layers 215a and the word line electrode layers 215b exposed on the second capping layer 240 and in element isolation trenches Ti by performing an etch-back process.

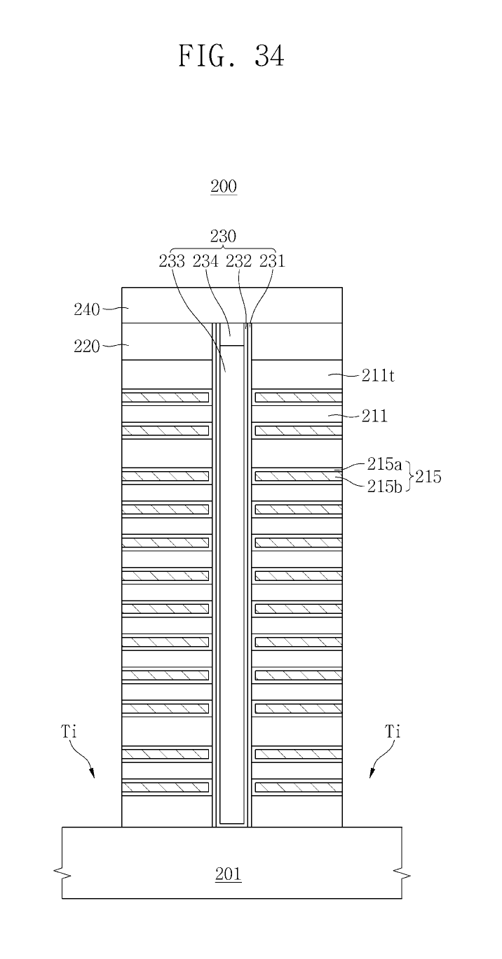

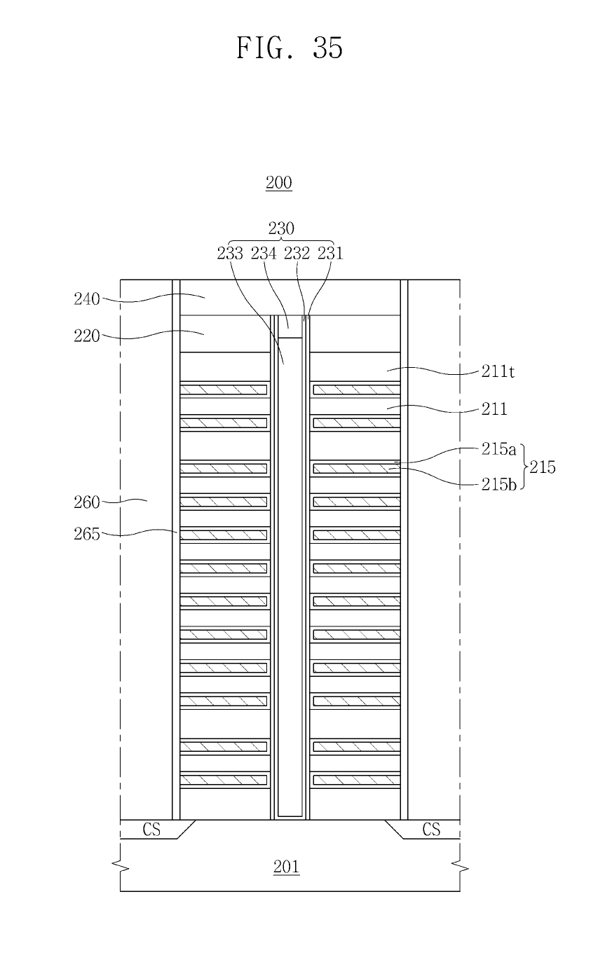

Referring to FIG. 35, the method may include forming spaces 265 on inner walls of the element isolation trenches Ti, forming common source electrodes CS in the substrate 201 exposed in the element isolation trenches Ti, and forming element isolation patterns 260 in order to fill up the element isolation trenches Ti. The spaces 265 may include silicon oxide or silicon nitride. Forming the common source electrodes CS may include injecting elements, such as phosphorus (P), arsenic (As), or boron (B) into the substrate 201, but are not limited thereto. The element isolation patterns 260 may include silicon oxide.

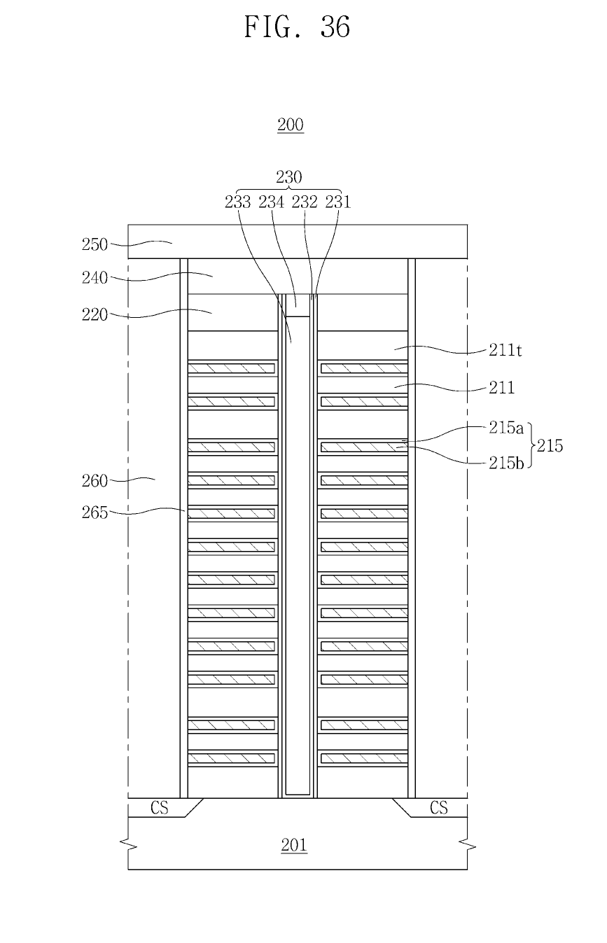

Referring to FIG. 36, the method may include forming a third capping layer 250 covering the element isolation patterns 260 and the second capping layer 240. Forming the third capping layer 250 may include forming silicon oxide on the element isolation patterns 260 and the second capping layer 240 by performing a deposition process.

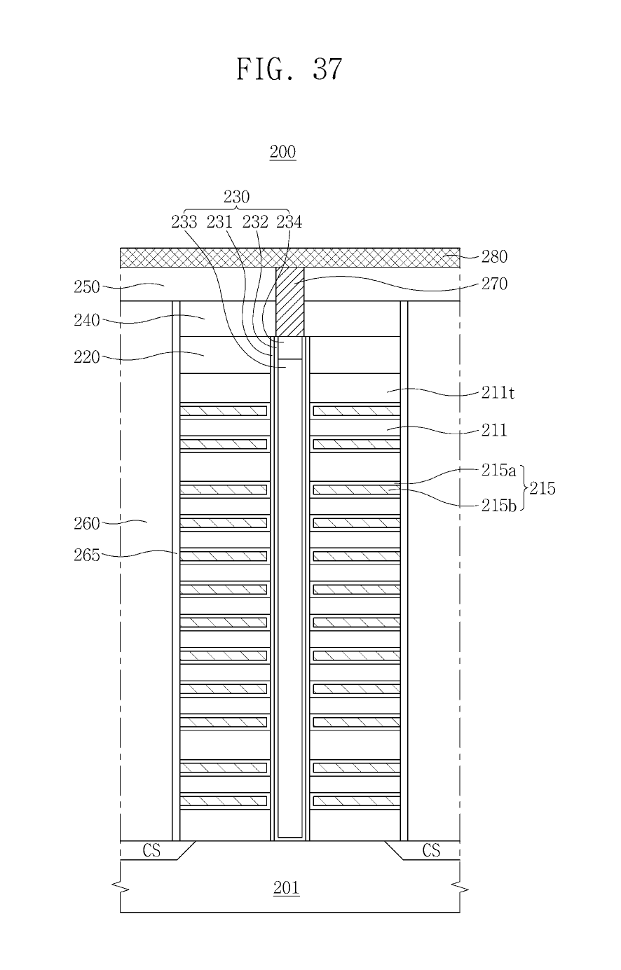

Referring to FIG. 37, the method may include forming a bit line plug 270 electrically connected to the channel pad layer 234, and forming a bit line 280 electrically connected to the bit line plug 270 on the third capping layer 250. Forming the bit line plug 270 may include, forming a via hole exposing the top surface of the channel pad layer 234 in the channel structure 230 by vertically passing through the second and third capping layers 240 and 250 by performing an etching process, and filling a conductive material in the via hole. The bit line plug 270 may include a metal, a metal compound, and/or a metal silicide. Sides of the bit line plug 270 may be surrounded by the second and third capping layers 240 and 250. The bit line 280 may include a metal or a metal compound.

FIGS. 38 through 52 are longitudinal sectional views for describing a method of fabricating a semiconductor device 300 in accordance with an exemplary embodiment of the present general inventive concept. The semiconductor device 300 may include a semiconductor device having a contact plug.

Referring to FIG. 38, the method may include forming one or more unit devices 310 in and/or on a substrate 301, forming an inner circuit 320 electrically connected to the unit devices 310, forming an interlayer insulating layer 330 covering the unit devices 310 and the inner circuit 320 in the substrate 301, forming a silicon mask layer 510 on the interlayer insulating layer 330, forming a first mask layer 520 on the silicon mask layer 510, forming a second mask layer 530 on the first mask layer 520, and forming a mask pattern 540a on the second mask layer 530.

Here, the substrate 301 may include a single crystal silicon wafer, an SOI wafer, and a silicon-germanium wafer, but is not limited thereto.

The unit devices 310 may be formed in and/or on the substrate 301. The unit devices 310 may include MOS transistors. Although the unit devices 310 are described as one unit device in FIG. 38, the unit devices 310 may also form a plurality of unit devices.

Here, the inner circuit 320 may include conductive inner wires electrically connected to the unit devices 310. The inner circuit 320 may include conductors, such as doped silicon, a metal, a metal silicide, a metal alloy, and a metal compound, but is not limited thereto.

In some exemplary embodiments of the present general inventive concept, forming the interlayer insulating layer 330 may include forming a silicon oxide layer on the substrate 301 by performing a deposition process. Although the interlayer insulating layer 330 is described as a single layer in FIG. 38, multiple layers may be formed. The interlayer insulating layer 330 may include a material having a different etch selectivity from the substrate 301.

Forming the silicon mask layer 510 may include forming polycrystalline silicon entirely on the interlayer insulating layer 330 by performing a deposition process. The silicon mask layer 510 may have a different etch selectivity from the interlayer insulating layer 330.

Forming the first mask layer 520 may include forming a carbon-based material entirely on the silicon mask layer 510 by performing a deposition or coating process. The first mask layer 520 may include a material having a different etch selectivity from the silicon mask layer 510. For example, forming the first mask layer 520 may include forming an ACL entirely on the silicon mask layer 510 by performing a CVD process. Furthermore, forming the first mask layer 520 may include forming an SOH entirely on the silicon mask layer 510 by performing a coating process.

Forming the second mask layer 530 may include forming an inorganic material entirely on the first mask layer 520 by performing a deposition process. The second mask layer 530 may include a material having a different etch selectivity from the first mask layer 520. For example, forming the second mask layer 530 may include forming one of silicon oxide (SiO₂), silicon nitride (Si₃N₄), and silicon oxynitride (SiON) entirely on the first mask layer 520 by performing a deposition process.

Forming the mask pattern 540a may include forming a material having a different etch selectivity from the second mask layer 530 on the second mask layer 530 by performing a deposition process, and forming a hole H selectively exposing the second mask layer 530 by performing a photolithography process. For example, the mask pattern 540a may include a photoresist.

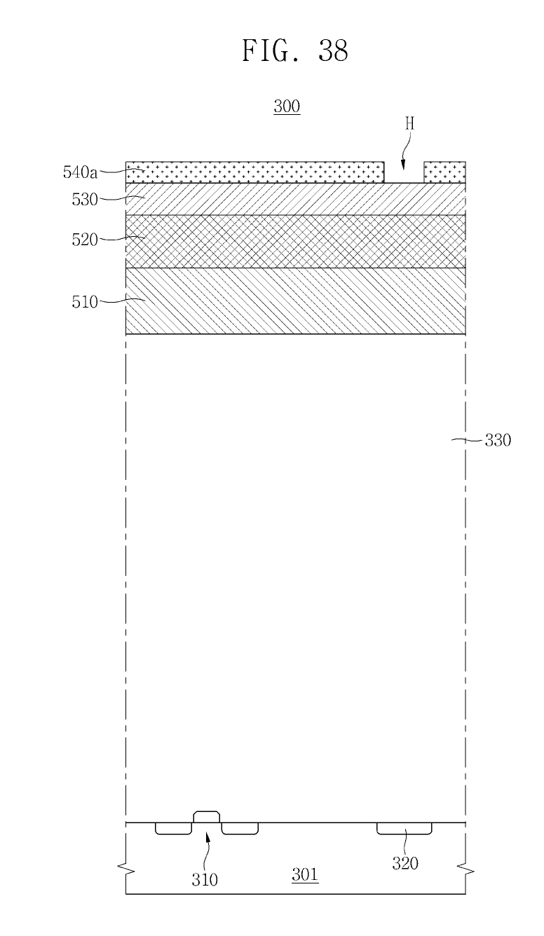

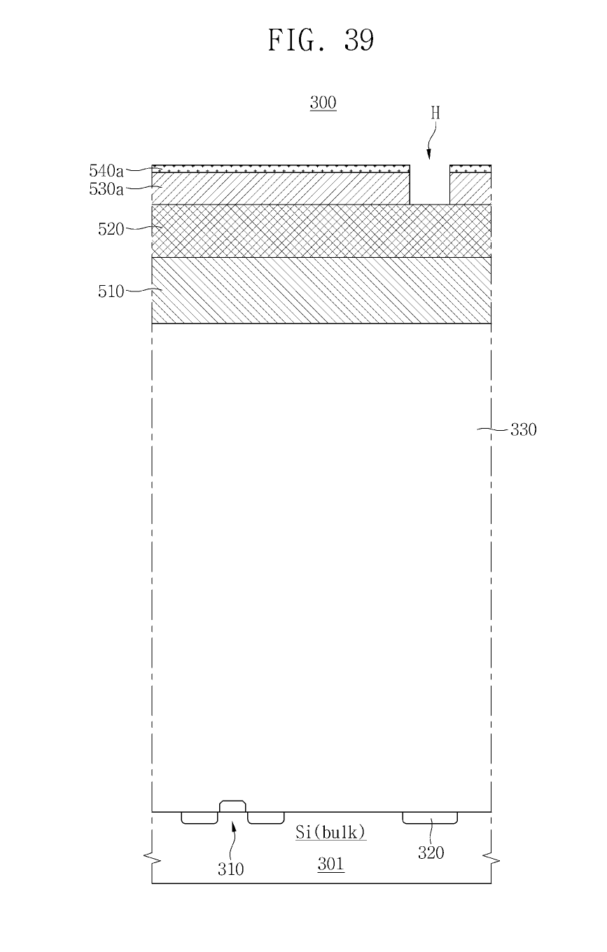

Referring to FIG. 39, the method may include selectively removing the second mask layer 530 using the mask pattern 540a as an etching mask. In this process, the second mask layer 530 may be patterned with a second mask pattern 530a, and the mask pattern 540a may become thinner. The first mask layer 520 may be exposed in the hole H.

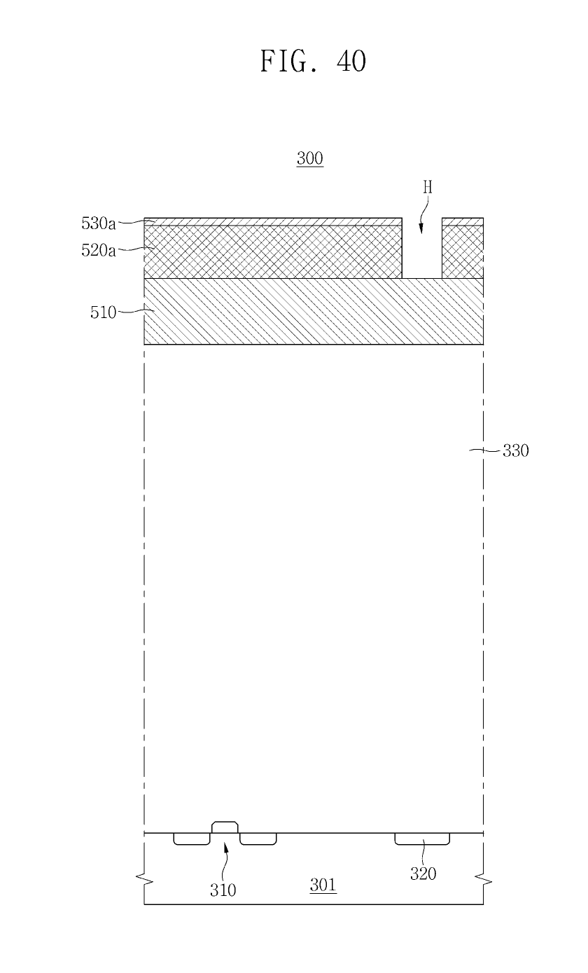

Referring to FIG. 40, the method may include selectively removing the first mask layer 520 using the mask pattern 540a and the second mask pattern 530a as etching masks. In this process, the first mask layer 520 may be patterned with a first mask pattern 520a, and the second mask pattern 530a may become thinner. In addition, all of the mask pattern 540a may be removed. The silicon mask layer 510 may be exposed in the hole H.

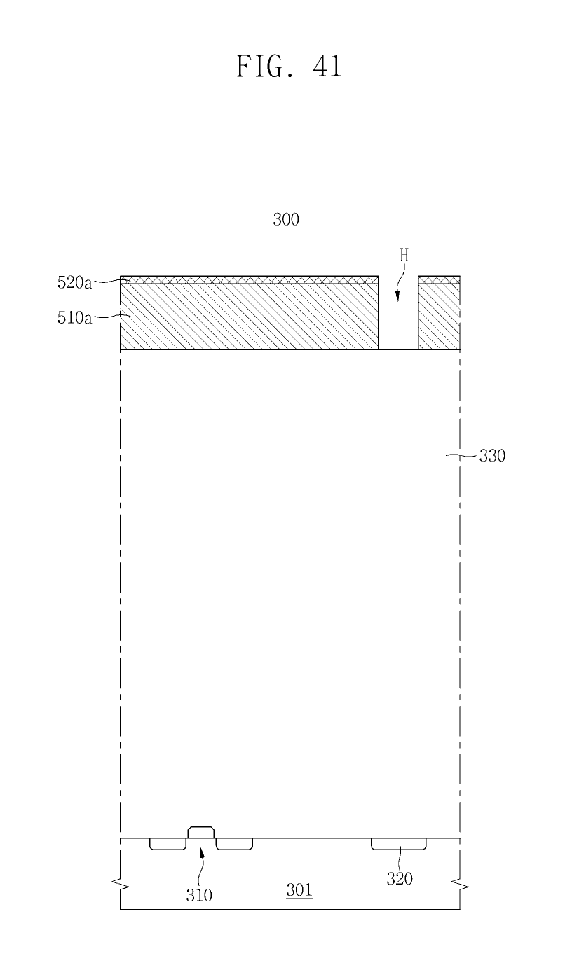

Referring to FIG. 41, the method may include selectively removing the silicon mask layer 510 using the second mask pattern 530a and the first mask pattern 520a as etching masks. In this process, the silicon mask layer 510 may be patterned with a silicon mask pattern 510a, and the first mask pattern 520a may become thinner. In addition, all of the second mask pattern 530a may be removed. The interlayer insulating layer 330 may be exposed through the hole H.

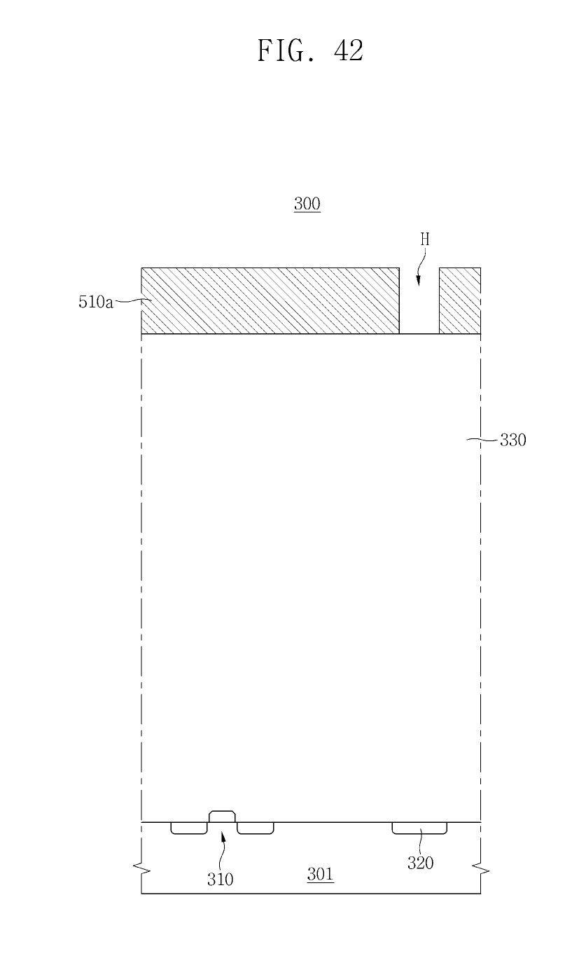

Referring to FIG. 42, the method may include removing the thinned first mask pattern 520a by performing an etch-back and/or ashing process.

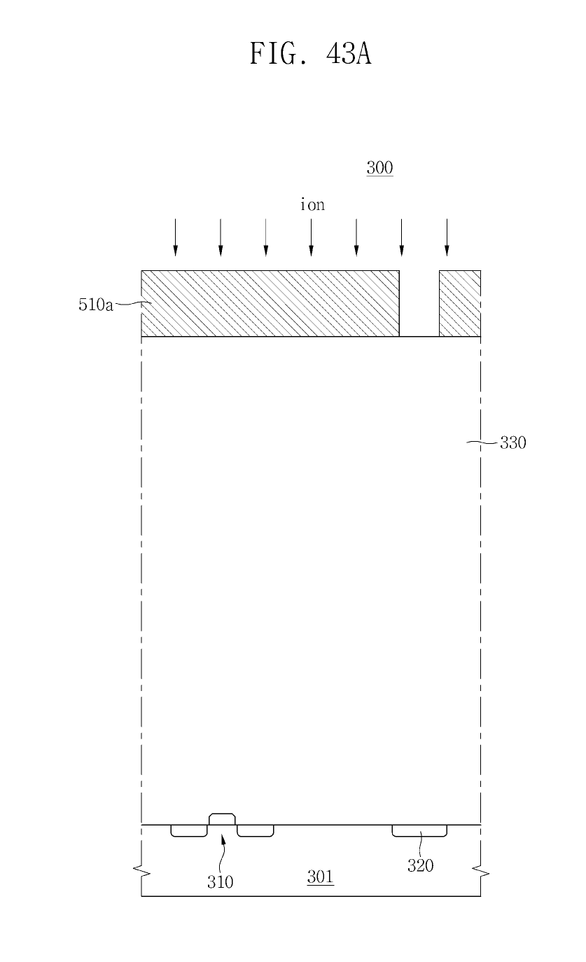

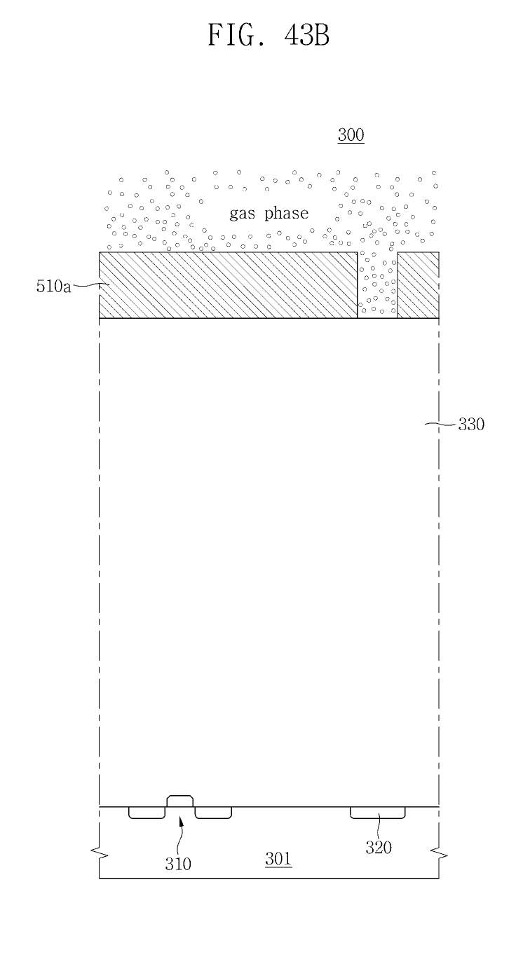

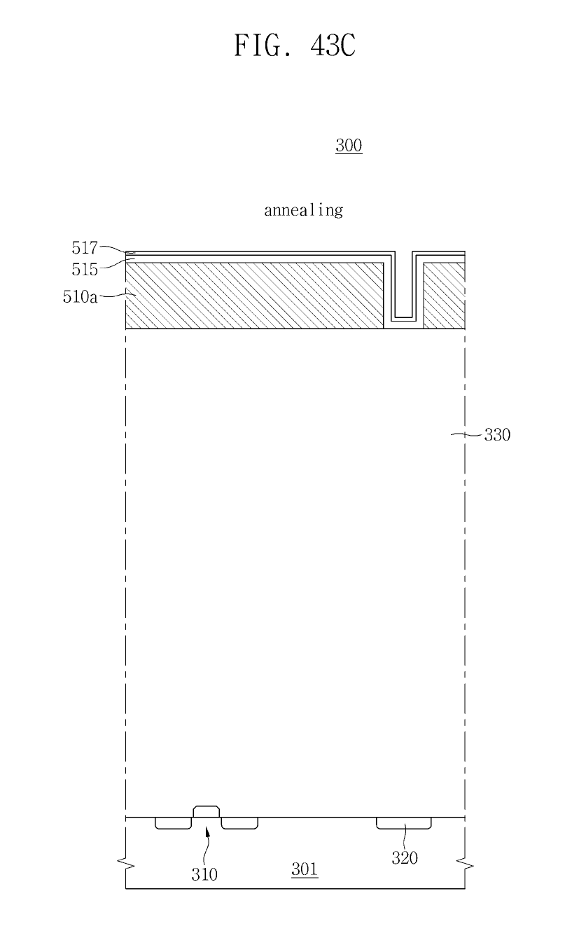

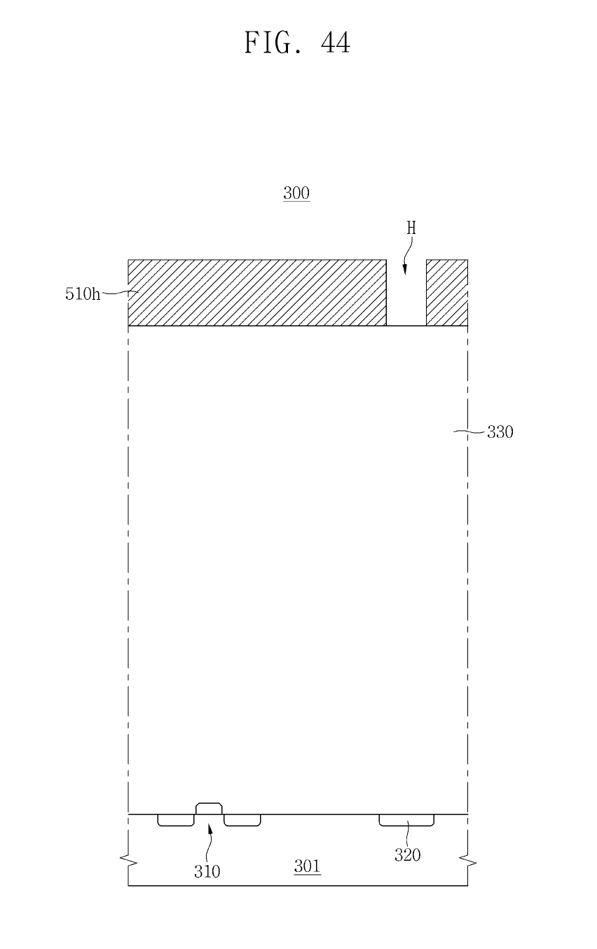

Referring to FIGS. 43A through 43C and 44, the method may include changing the silicon mask pattern 510a to a hard mask pattern 510h as described with reference to FIG. 44. Changing the silicon mask pattern 510a to the hard mask pattern 510h may include doping impurities into the silicon mask pattern 510a. For example, the impurities may include boron (B), argon (Ar), carbon (C), and phosphorus (P), but are not limited thereto.

Referring to FIG. 43A, doping the impurities into the silicon mask pattern 510a may include directly injecting the impurities into the silicon mask pattern 510a by an ion implantation process.

Referring to FIG. 43B, doping the impurities into the silicon mask pattern 510a may include performing an annealing process in a chamber in which gases including impurities are injected. The annealing process may be performed at a temperature within a range of about 500° C. to 800° C. In this process, the impurities included in the gases may be doped into the silicon mask pattern 510a in a gas phase. For example, boron (B) may be doped into the silicon mask pattern 510a when diborane (B₂H₆) or boron trichloride (BCl₃) gas is used, and carbon (C) may be doped into the silicon mask pattern 510a when ethylene (C₂H₄) gas is used. Thus, when the impurities are doped into the silicon mask pattern 510a in a gas phase, the impurities may be doped into sides of the hole H as well as the top of the silicon mask pattern 510a.

Referring to FIG. 43C, doping the impurities into the silicon mask pattern 510a may include conformally forming a heterogeneous film 515 on the surface of the silicon mask pattern 510a, and performing an annealing process. Forming the heterogeneous film on the silicon mask pattern 510a may include forming one of BSG, PSG, and ASG on the surface of the silicon mask pattern 510a by performing a deposition process, such as CVD or ALD, but is not limited thereto. Performing the annealing process may include performing spike annealing at a temperature within a range of about 950° C. to 1050° C. Performing the spike annealing may prevent degradation of a semiconductor device 300 caused by a heat budget. Inter-diffusion of the impurities occurs between the silicon mask pattern 510a and the heterogeneous film 515 when the annealing process is performed, and thus the impurities of the heterogeneous film 515 may be doped into the silicon mask pattern 510a.

Meanwhile, a method of doping the impurities using the heterogeneous film 515 may further include after forming the heterogeneous film 515 on the silicon mask pattern 510a, conformally forming a heterogeneous film capping layer 517 on the heterogeneous film 515. The heterogeneous film capping layer 517 may prevent emission of impurities from the heterogeneous film 515 to the outside in the annealing process.

Referring to FIG. 44, a hard mask pattern 510h changed from the silicon mask pattern 510a may be formed as described with reference to FIGS. 43A through 43C. The hard mask pattern 510h may have a higher etch selectivity than the silicon mask pattern 510a. Etch selectivity of the hard mask pattern 510h may be varied based on types and concentrations of the impurities doped into the silicon mask pattern 510a. For example, etch selectivity of the hard mask pattern 510h may be more improved in the case of doping carbon (C) than doping boron (B) as the impurities at the same concentrations of carbon (C) and boron (B). In addition, the etch selectivity of the hard mask pattern 510h may be improved according to increasing concentration of the impurities doped into the silicon mask pattern 510a. Concentration of the impurities may be at least about 2% of the silicon concentration of the silicon mask pattern 510a. When concentration of the impurities is about 5%, the etch selectivity of the hard mask pattern 510h may be increased about 30%-50% more than etch selectivity of the silicon mask pattern 510a. For example, when the etch selectivity of the silicon mask pattern 510a is 6:1, and boron (B) corresponding to about 5% of the silicon concentration of the silicon mask pattern 510a is doped into the silicon mask pattern 510a, the silicon mask pattern 510a may be changed to the hard mask pattern 510h in which etch selectivity is improved to about 7.8:1. In addition, when carbon (C) corresponding to about 5% of the silicon concentration of the silicon mask pattern 510a is doped into the silicon mask pattern 610a, the silicon mask pattern 510a may be changed to the hard mask pattern 510h in which etch selectivity is improved to about 9:1.

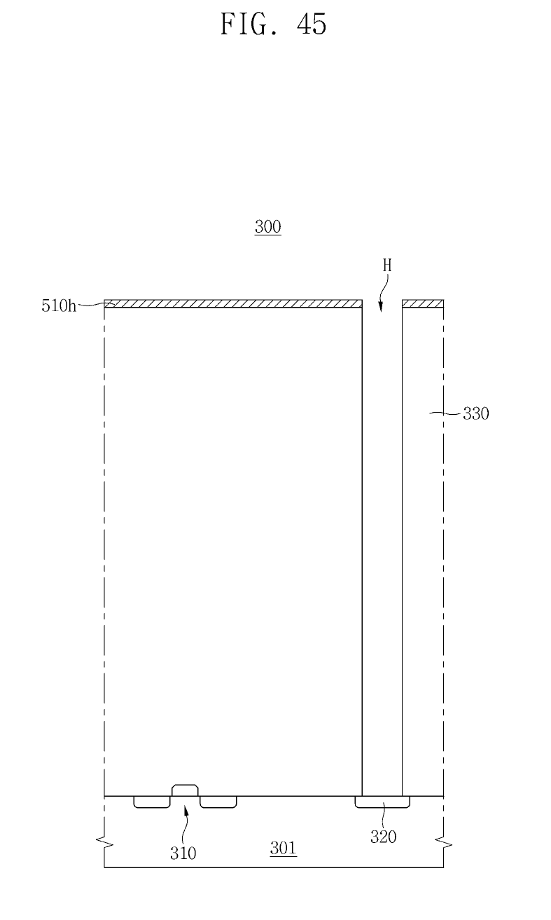

Referring to FIG. 45, the method may include selectively removing the interlayer insulating layer 330 using the hard mask pattern 510h as an etching mask. In this process, the hole H having an HARC structure may be formed, and the hard mask pattern 510h may become thinner. The inner circuit 320 may be exposed in the hole H.

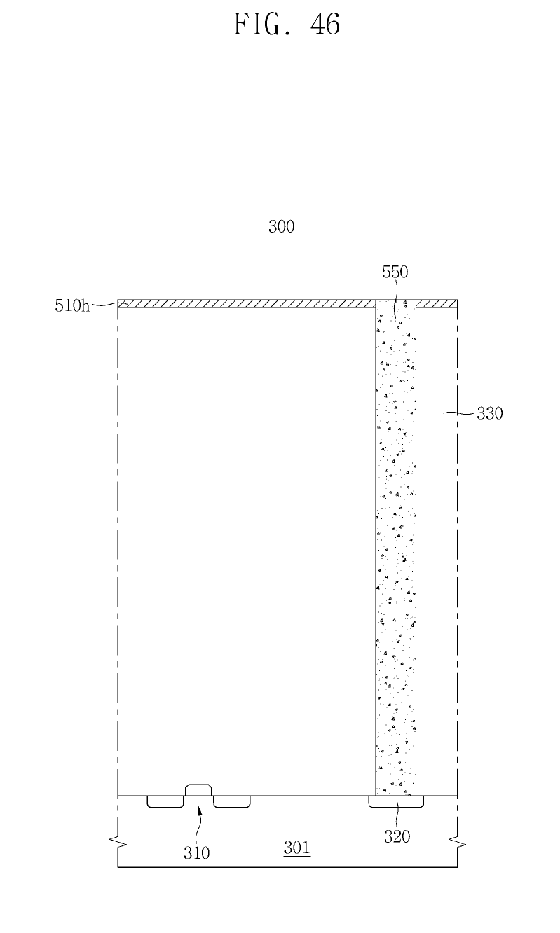

Referring to FIG. 46, the method may include filling a sacrificial layer 550 in the hole H. The sacrificial layer 550 may include a material having a different etch selectivity from the interlayer insulating layer 330. For example, the sacrificial layer 550 may include organic matters such as a resist, a photoresist, an organic resin, or an organic polymer, but is not limited thereto.

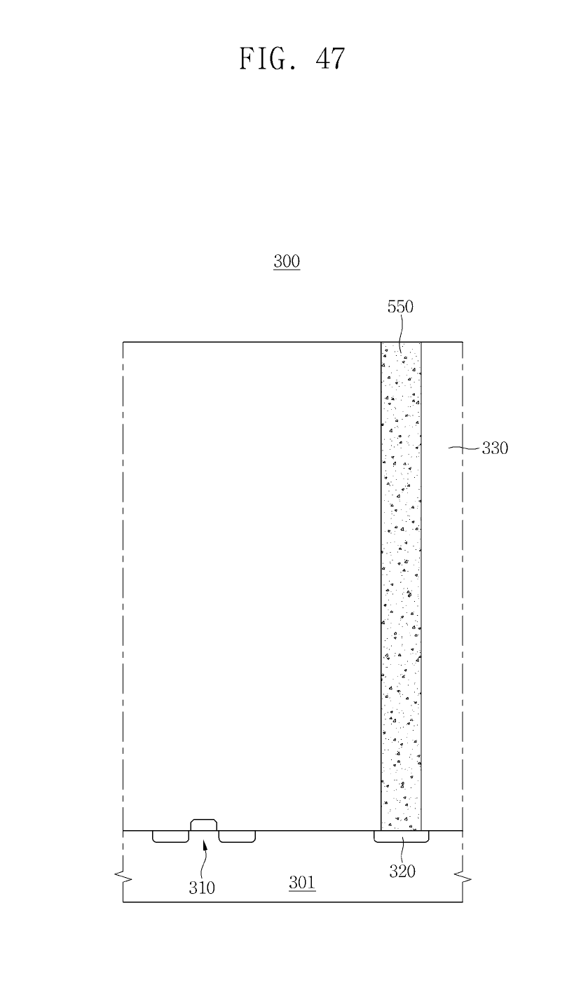

Referring to FIG. 47, the method may include removing the thinned hard mask pattern 510h. Removing the hard mask pattern 510h may include performing a wet etching process using an etchant including ammonia water. Furthermore, removing the hard mask pattern 510h may include exposing the interlayer insulating layer 330 by performing a planarization process such as CMP, but is not limited thereto.

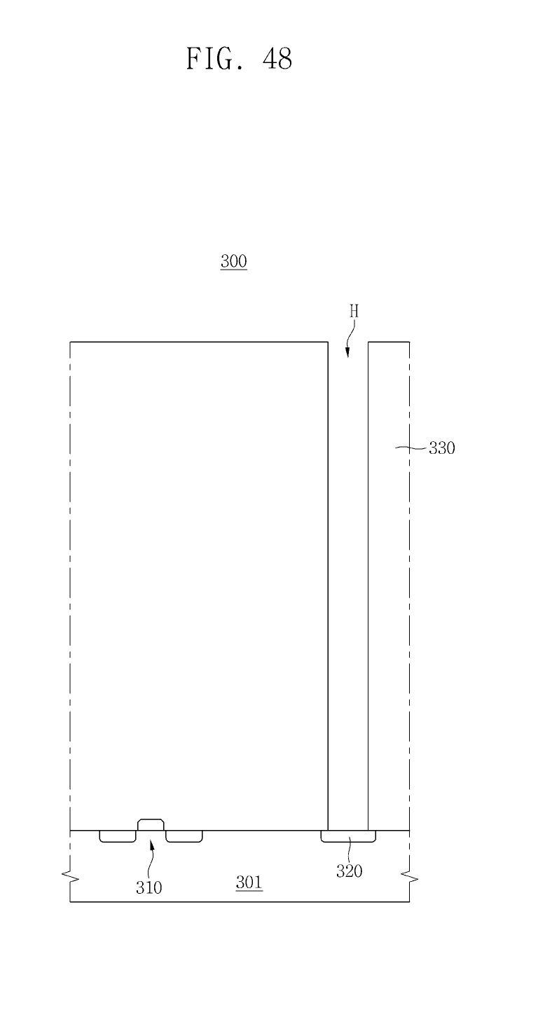

Referring to FIG. 48, the method may include removing the sacrificial layer 550. Removing the sacrificial layer 550 may include performing an ashing process using oxygen (O₂) gas.

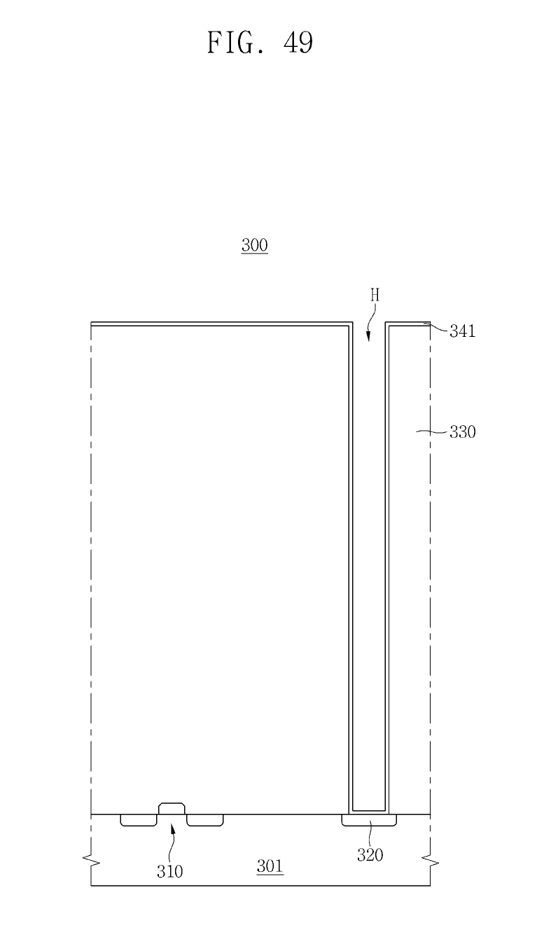

Referring to FIG. 49, conformally forming a contact plug barrier layer 341 on the interlayer insulating layer 330 and inner walls of the hole H may be included. The contact plug barrier layer 341 may be formed by performing a deposition process using titanium (Ti), titanium nitride (TiN), tantalum (Ta), tantalum nitride (TaN), titanium tungsten (TiW), tungsten silicide (WSi), or another barrier metal, but is not limited thereto.

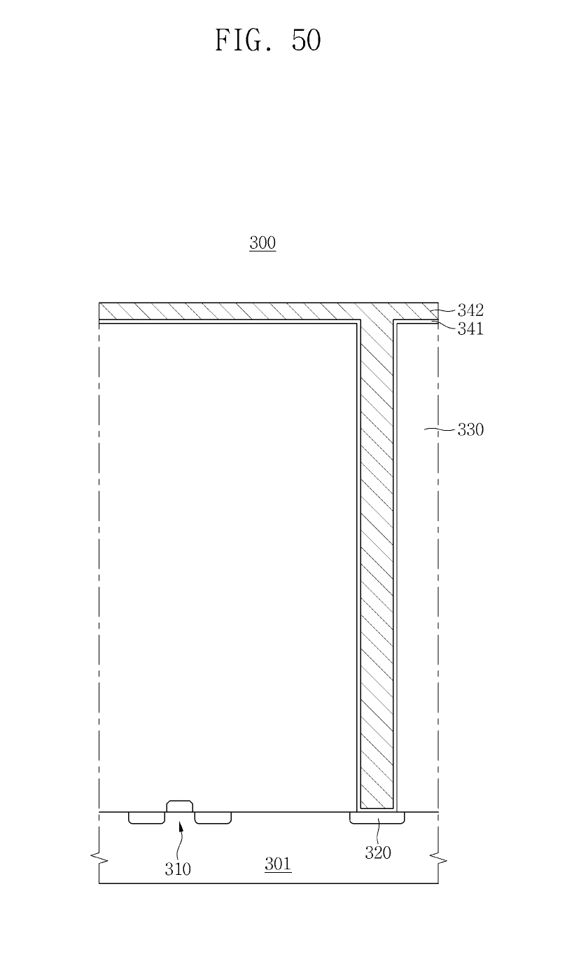

Referring to FIG. 50, the method may include forming a contact plug core layer 342 on the contact plug barrier layer 341 to fill the inside of the hole H. The contact plug core layer 342 may include a metal compound or a metal silicide. Furthermore, the contact plug core layer 342 may include polysilicon. When the contact plug core layer 342 is polysilicon, forming the contact plug barrier layer 341 described with reference to FIG. 49 may be omitted.

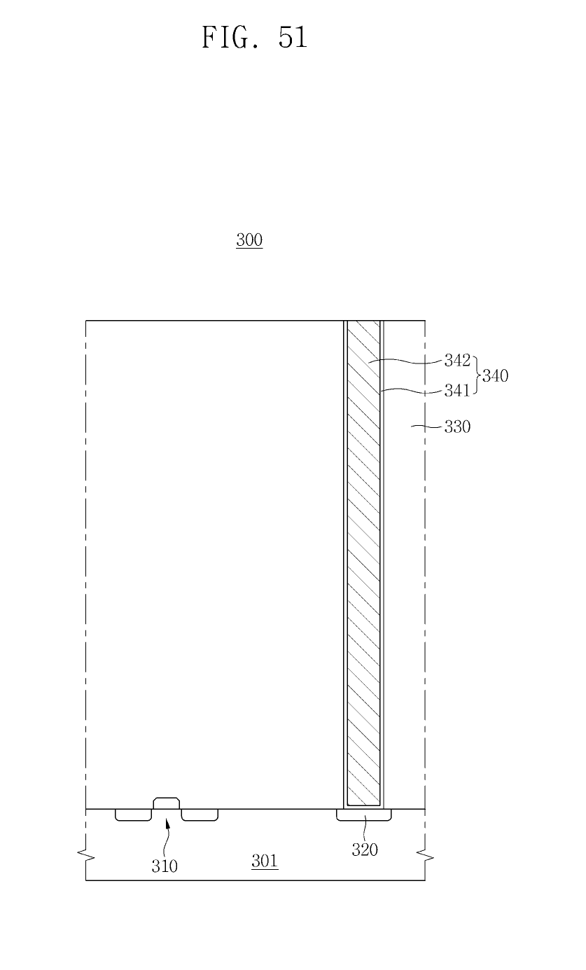

Referring to FIG. 51, the method may include exposing the interlayer insulating layer 330 by performing a planarization process such as CMP, but is not limited thereto. In this process, a contact plug 340 including the contact plug barrier layer 341 and the contact plug core layer 342 in the hole H may be formed.

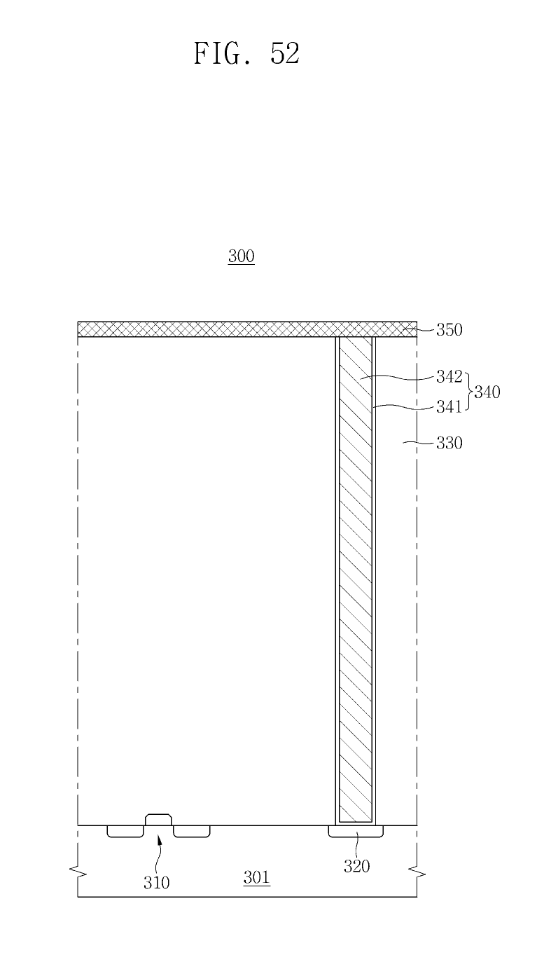

Referring to FIG. 52, the method may include forming a wire layer 350 electrically connected to the contact plug 340. The wire layer 350 may include a metal or a metal compound. The wire layer 350 may include a bit line.

So far, as described above, according to the method of fabricating the semiconductor devices 100, 200 and 300, when a silicon mask is patterned and changed to a hard mask having improved etch selectivity, a shortage of the hard mask in an HARC process may be prevented and the thickness of mask may also become thinner. In addition, when a patterning process is performed prior to changing to the hard mask, patterning of the silicon mask may become easier.

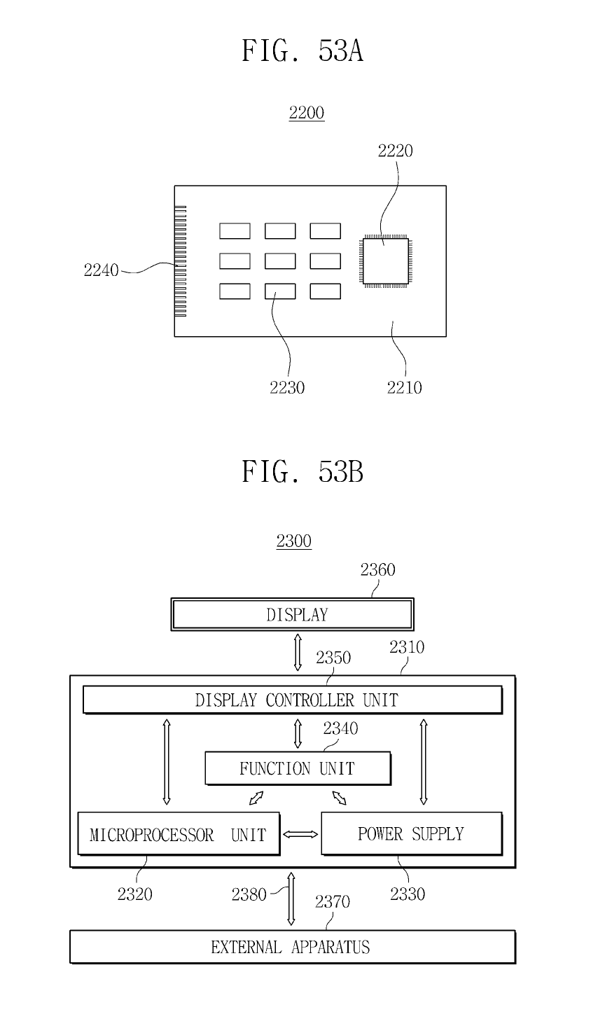

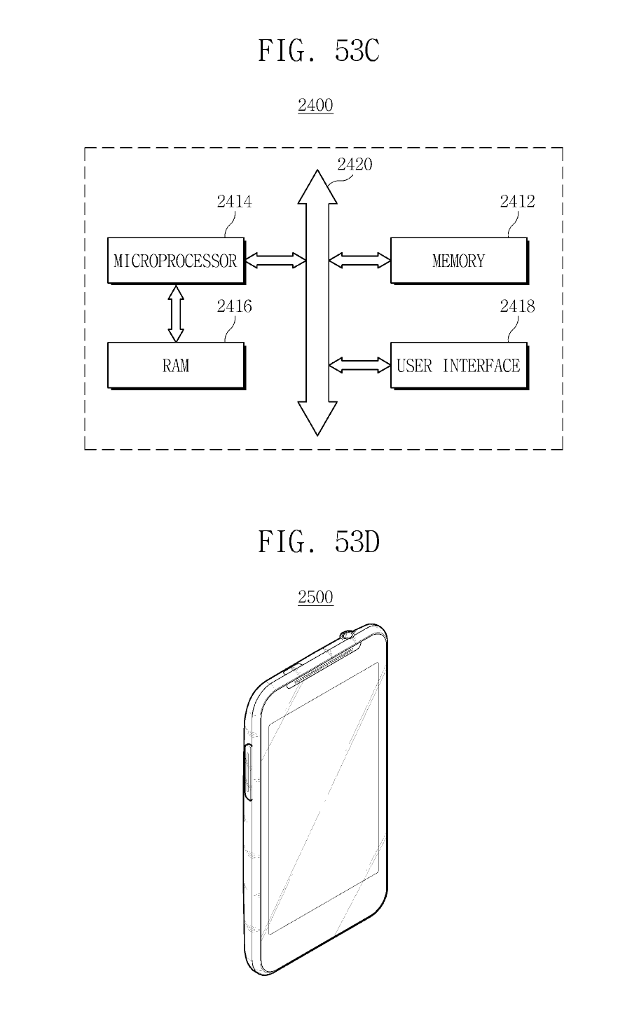

FIG. 53A is a schematic view illustrating a semiconductor module 2200 including semiconductor devices 100, 200, and 300 in accordance with various embodiments of the inventive concept. Referring to FIG. 53A, the semiconductor module 2200 in accordance with an embodiment of the inventive concept may include semiconductor devices 2230 installed on a semiconductor module substrate 2210. Each of the semiconductor devices 2230 may be any one of the semiconductor devices 100, 200 and 300 based on various embodiments of the inventive concept. The semiconductor module 2200 may further include a microprocessor 2220 installed on the semiconductor module substrate 2210. Input/output terminals 2240 may be disposed on at least one side of the semiconductor module substrate 2210.

FIG. 53B is a schematic block diagram illustrating an electronic system including semiconductor devices 100, 200, and 300 in accordance with various embodiments of the inventive concept. The semiconductor devices 100, 200, and 300 in accordance with various exemplary embodiments of the present general inventive concept may be applied to an electronic system 2300. The electronic system 2300 may include a body 2310. The body 2310 may include a microprocessor unit 2320, a power supply 2330, a function unit 2340, and/or a display controller unit 2350. The body 2310 may be a system board or a motherboard having a printed circuit board (PCB), but is not limited thereto.

The microprocessor unit 2320, the power supply 2330, the function unit 2340, and the display controller unit 2350 may be installed or arranged on the body 2310. A display 2360 may be disposed on top of the body 2310 or outside of the body 2310. For example, the display 2360 disposed on the surface of the body 2310 may display an image processed by the display controller unit 2350. The power supply 2330 in which a predetermined voltage is supplied from an external power or the like may be divided into various voltage levels, and supplied to the microprocessor unit 2320, the function unit 2340, and the display controller unit 2350.

The microprocessor unit 2320 in which a voltage is supplied from the power supply 2330 may control the function unit 2340 and the display 2360. The function unit 2340 may perform various functions of the electronic system 2300. For example, when the electronic system 2300 is a mobile electronic apparatus, such as a mobile phone, the function unit 2340 may include various configuring elements to perform a wireless communication function, such as displaying an image on the display 2360, outputting a voice from a speaker, but is not limited thereto, through communication through dialing or an external apparatus 2370, and when a camera is included, a role of an image processor may be performed.

In another exemplary embodiment of the present general inventive concept, when the electronic system 2300 is connected to a memory card or the like to expand capacity, the function unit 2340 may be a memory card controller. The function unit 2340 may exchange signals with an external apparatus 2370 through a wire or wireless communication unit 2380. In addition, when the electronic system 2300 requires a Universal Serial Bus (USB) or the like, in order to expand functions, the function unit 2340 may perform a role of an interface controller. The semiconductor devices 100, 200 and 300 in accordance with various embodiments of the inventive concept may be included in at least one of the microprocessor unit 2320 and the function unit 2340.

FIG. 53C is a schematic block diagram illustrating another electronic system 2400 including semiconductor devices 100, 200 and 300 in accordance with various exemplary embodiments of the present general inventive concept. Referring to FIG. 53C, the electronic system 2400 may include the semiconductor devices 100, 200, and 300 based on various embodiments of the inventive concept. The electronic system 2400 may be used to fabricate a mobile apparatus or a computer. For example, the electronic system 2400 may include a user interface 2418 to perform data communication using a memory system 2412, a microprocessor 2414, a RAM 2416, and a bus 2420. The microprocessor 2414 may program and control the electronic system 2400. The RAM 2416 may be used for an operating memory of the microprocessor 2414. For example, the microprocessor 2414 or the RAM 2416 may include semiconductor devices 100, 200, and 300. The microprocessor 2414, the RAM 2416 and/or other configuring elements may be assembled in a single package. The user interface 2418 may be used to input or output data to or from the electronic system 2400. The memory system 2412 may store operating codes of the microprocessor 2414, data handled by the microprocessor 2414, or external input data. The memory system 2412 may include a controller and a memory.

FIG. 53D is a schematic view illustrating a mobile apparatus 2500 including at least one of semiconductor devices 100, 200, and 300 in accordance with various embodiments of the inventive concept. The mobile apparatus 2500 may include a mobile phone or a tablet PC. In addition, the semiconductor devices 100, 200, and 300 may be used for a portable computer, such as a notebook, an MPEG-1 audio layer 3 (MP3) player, an MP4 player, a navigation apparatus, a solid state disk (SSD), a table computer, a vehicle, and a home electronic product as well as a mobile phone or a tablet PC, but are not limited thereto.

Methods of fabricating a semiconductor device according to various exemplary embodiments of the present general inventive concept include after patterning a silicon mask, changing the silicon mask to a hard mask having improved etch selectivity, and thus shortage of the hard mask in an HARC process can be prevented and the thickness of mask also can become thinner. In addition, when the patterning process is performed prior to changing to the hard mask, patterning a silicon mask can become easier. As a result, process stability and reliability can be obtained.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of fabricating a semiconductor device, comprising:
forming one or more molding layers on a substrate;
forming a silicon mask layer, first and second mask layers, and a mask pattern having a different etch selectivity to be vertically aligned on the molding layers;
patterning the second mask layer with a second mask pattern using the mask pattern as an etching mask;
patterning the first mask layer with a first mask pattern using the second mask pattern as an etching mask;
patterning the silicon mask layer with a silicon mask pattern using the first mask pattern as an etching mask;
changing the silicon mask pattern to a hard mask pattern in which etch selectivity is improved by doping impurities into the silicon mask pattern;
forming a hole having a high aspect ratio contact (HARC) structure vertically passing through the molding layers using the hard mask pattern as an etching mask; and
removing the hard mask pattern.

2. The method of claim 1, wherein the impurities include one of boron (B), argon (Ar), carbon (C) and phosphorus (P).

3. The method of claim 1, wherein the first mask layer includes one of an amorphous carbon layer (ACL) and a spin-on hard mask (SOH).

4. The method of claim 1, wherein the second mask layer includes one of silicon oxide, silicon nitride, and silicon oxynitride.

5. The method of claim 1, wherein the mask pattern includes a photoresist.

6. The method of claim 1, wherein changing the silicon mask pattern to a hard mask pattern includes directly doping the impurities into the silicon mask pattern by performing an ion implantation process.

7. The method of claim 1, wherein changing the silicon mask pattern to a hard mask pattern includes doping the impurities into the silicon mask pattern in a gas phase by performing an annealing process in a chamber in which gases including the impurities are injected.

8. The method of claim 7, wherein the annealing process is performed at a temperature within a range of 500° C. to 800° C.

9. The method of claim 1, wherein changing the silicon mask pattern to a hard mask pattern includes;
conformally forming a heterogeneous film on the silicon mask pattern by performing a deposition process; and
doping the impurities into the silicon mask pattern by inter-diffusion of the impurities between the silicon mask pattern and the heterogeneous film by performing an annealing process.

10. The method of claim 9, wherein the heterogeneous film includes one of boron silicate glass (BSG), phosphorus silicate glass (PSG) and arsenic silicate glass (ASG).

11. The method of claim 9, wherein the annealing process includes spike annealing at a temperature within a range of 950° C. to 1050° C.

12. The method of claim 9, further comprising:
after forming the heterogeneous film, conformally forming a heterogeneous film capping layer on the heterogeneous film.

13. The method of claim 1, wherein removing the hard mask pattern includes performing a wet etching process using an etchant including ammonia water.

14. The method of claim 1, wherein removing the hard mask pattern includes:
forming a sacrificial layer in the hole;
exposing the molding layers by performing a planarization process; and
removing the sacrificial layer.

15. A method of fabricating a semiconductor device, comprising:
forming a unit device on or in a substrate;
forming a molding layer covering the unit device on or in the substrate;
forming a silicon mask layer on the molding layer;
patterning the silicon mask layer with a silicon mask pattern;
changing the silicon mask pattern to a hard mask pattern by doping impurities into the silicon mask pattern;
forming a hole having a high aspect ratio contact (HARC) structure vertically passing through the molding layer using the hard mask pattern as an etching mask, and exposing the substrate or the unit device;
removing the hard mask pattern; and
forming a capacitor structure or a contact plug electrically connected to the substrate or the unit device in the hole.

16. A method of fabricating a semiconductor device, comprising:
forming a silicon mask layer on a top surface of a molding layer, the silicon layer being partially covered by at least one mask pattern;
patterning the silicon mask layer using the at least one mask pattern to form a silicon mask pattern;
changing the silicon mask pattern to a hard mask pattern having an increased etch selectivity; and
forming a hole vertically passing through the hard mask pattern and the molding layer using the hard mask pattern as an etch mask to expose an electrical component covered by the molding layer.

17. The method of claim 16, wherein the at least one mask pattern includes a first mask pattern from a first mask pattern and a second mask pattern from a second mask layer, such that the first and the second mask patterns are vertically aligned with each other and the first mask pattern is used as an etch mask for the silicon mask layer to form the silicon mask pattern.

18. The method of claim 16, wherein the silicon mask pattern is doped with impurities to form the hard mask pattern.

19. The method of claim 18, wherein doping the impurities includes at least one of directly doping the impurities by an ion implantation process, injecting gases including the impurities by an annealing process, and inter-diffusing the impurities by an annealing process between the silicon mask pattern and a heterogeneous film disposed on top of the silicon mask pattern.

20. The method of claim 16, wherein the hole has a high aspect ratio contact (HARC) structure.
